(19) United States
(12) Patent Application Publication
(10) Pub. No.: US 2025/0259775 A1
(43) Pub. Date: Aug. 14, 2025

(54) POWER MODULE

(71) Applicant: Delta Electronics (Shanghai) Co., Ltd., Shanghai (CN)

(72) Inventors: Lin LAN, Shanghai (CN); Quanliang ZHANG, Shanghai (CN); Weiqiang ZHANG, Shanghai (CN); Yicong XIE, Shanghai (CN); Rui LI, Shanghai (CN)

(21) Appl. No.: 19/192,378

(22) Filed: Apr. 29, 2025

Related U.S. Application Data
(63) Continuation-in-part of application No. 18/818,606, filed on Aug. 29, 2024.

(30) Foreign Application Priority Data
Aug. 30, 2023 (CN) 202311115258.1
Feb. 8, 2025 (CN) 202520202924.3

(51) Int. Cl. H01F 27/24; H01F 27/28; H05K 1/02; H05K 1/18

(52) U.S. Cl. CPC H01F 27/24; H01F 27/28; H05K 1/0216; H05K 1/181; H05K 2201/1003

(57) ABSTRACT

A power module includes an insulating board, a transformer and a first shielding layer. The insulating board includes a flat plate portion. The transformer includes a magnetic core and a first winding wound on the magnetic core, where the first winding includes a first part and a second part connected electrically, where the first part is located on one side of the insulating board away from the magnetic core, and the second part is set within the insulating board. The first shielding layer is set at least on one side of the insulating board facing towards the magnetic core. In a first reference plane parallel to the flat plate portion, a projection of the magnetic core is located in a projection range of the first shielding layer.

### CROSS-REFERENCE TO RELATED APPLICATIONS

This application is a continuation-in-part application of U.S. application Ser. No. 18/818,606, filed on Aug. 29, 2024 entitled “POWER MODULE”, which claims priority to Chinese Patent Application No. 202311115258.1, filed on Aug. 30, 2023. This application further claims priority to Chinese Patent Application No. 202520202924.3, filed on Feb. 8, 2025. The disclosures of the aforementioned applications are hereby incorporated by reference in their entireties.

### TECHNICAL FIELD

The present application relates to the field of electrical equipment technologies and, in particular, to a power module.

### BACKGROUND

A power module is a module that combines multiple electronic devices according to certain functions, is mainly used to control power output and electric energy conversion in circuits, and is widely used in various electronic devices.

In the solutions of related technologies, the power module includes a shell, and a transformer and a voltage power device set inside the shell, the shell is provided with an insulating board therein, the transformer includes a magnetic core, a first winding and a second winding. The first winding and the second winding are respectively connected to the corresponding voltage power devices. At least two of the magnetic core, the first winding, and the second winding are arranged on an insulating board, and insulation is achieved between the magnetic core, the first winding, and the second winding through the insulating board.

However, in technical solutions of the related art, air among the magnetic core and the first and second windings will generate a large electric field. When there are sharp burrs on the edge of the magnetic core, discharge may occur, thereby affecting the insulation life.

### SUMMARY

In order to overcome the above defects under the relevant technologies, the purpose of the present application is to provide a power module that can improve an efficiency of a transformer in the power module. The present application is also beneficial for reducing the electric-field-strength in the air around the magnetic core, prolonging the insulation life, and improving the reliability of the product.

The present application provides a power module, including:
a first side plate, a second side plate, and an insulating board;
the insulating board including a flat plate portion, at least one protrusion portions, and at least one connecting bridges, the flat plate portion being parallel to a plane formed by a first direction and a second direction; at least one of the protrusion portion and the connecting bridge protruding along a third direction to form an insulation cavity; the insulating board, the first side plate, and the second side plate in combination forming a first accommodating space and a second accommodating space along the third direction; the first accommodating space being provided with a first power device, and the second accommodating space being provided with a second power device; and
a transformer, including a magnetic core and a winding wound on the magnetic core, the winding including a first winding and a second winding, at least part of the magnetic core being set within the insulation cavity or the connecting bridge; the first winding being electrically connected to the first power device, and the second winding being electrically connected to the second power device;
where the first direction, the second direction, and the third direction are perpendicular to each other.

In the present application, since the at least part of the magnetic core is set within the insulation cavity or the connecting bridge, the flat plate portion will not penetrate through an air gap of the magnetic core, thus facilitating a control of a size of the air gap of the magnetic core and is beneficial for improving an efficiency of the transformer in the power module; in addition, the protrusion portion or connecting bridge set on the flat plate portion enables the insulating board to form a bending structure, which is beneficial for improving an overall strength of the insulating board.

The present application further provides a power module, including:
an insulating board, comprising a flat plate portion;
a transformer, comprising a magnetic core and a first winding wound on the magnetic core, wherein the first winding comprises a first part and a second part connected electrically, wherein the first part is located on one side of the insulating board away from the magnetic core, and the second part is set within the insulating board;
a first shielding layer which is set at least on one side of the insulating board facing towards the magnetic core;
where in a first reference plane parallel to the flat plate portion, a projection of the magnetic core is located in a projection range of the first shielding layer.

The present application sets the first shielding layer on the side of the insulating board facing towards the magnetic core, and the projection of the magnetic core is located within the projection range of the first shielding layer, so that the first shielding layer can be used to reduce the electric-field-strength in the air around the magnetic core, prolong the insulation life, and improve the reliability of the product.

### BRIEF DESCRIPTION OF DRAWINGS

In order to explain the embodiments of the present application more clearly, the drawings needed to be used in the embodiments will be introduced briefly in the following. Obviously, the drawings in the following description are some embodiments of the present application. For those skilled in the art, other drawings can be obtained from these drawings without paying creative labor.

FIG. 1 is an external schematic diagram of a power module provided by an embodiment of the present application.

FIG. 2 is a structural diagram of a power module provided by an embodiment of the present application.

FIG. 3 is a structural diagram of an insulating board provided by an embodiment of the present application.

FIG. 4 is a structural diagram of an insulating board provided by another embodiment of the present application.

FIG. 5 is a structural diagram of a transformer provided by an embodiment of the present application.

FIG. 6 is a structural diagram of a transformer provided by another embodiment of the present application.

FIG. 7 is a schematic diagram of a connection structure of a transformer and an insulating board provided by an embodiment of the present application.

FIG. 8 is a schematic diagram of a connection structure of a transformer and an insulating board provided by another embodiment of the present application.

FIG. 9 is a schematic diagram of a connection structure of a transformer and an insulating board provided by still another embodiment of the present application.

FIG. 10 is a schematic diagram of a connection structure of a transformer and an insulating board provided by yet another embodiment of the present application.

FIG. 11 is a schematic diagram of a connection structure of a transformer and an insulating board provided by yet another embodiment of the present application.

FIG. 12 is a schematic diagram of a connection structure of a transformer and an insulating board provided by yet another embodiment of the present application.

FIG. 13 is a schematic diagram of a connection structure of a transformer and an insulating board provided by yet another embodiment of the present application.

FIG. 14 is a schematic diagram of a connection structure of a transformer and an insulating board provided by yet another embodiment of the present application.

FIG. 15 is a structural diagram of a power module provided by another embodiment of the present application.

FIG. 16 is a structural diagram of a power module provided by still another embodiment of the present application.

FIG. 17 is a structural diagram of a transformer provided by yet another embodiment of the present application.

FIG. 18 is a schematic diagram of a connection structure of a transformer and an insulating board provided by yet another embodiment of the present application.

FIG. 19 is a structural diagram of a magnetic core provided by yet another embodiment of the present application.

FIG. 20 is a structural diagram of a power module provided by an embodiment of the present application.

FIG. 21 is a side view of the FIG. 20.

FIG. 22 is an A-A sectional view of the FIG. 21.

FIG. 23 is a B-B sectional view of the FIG. 21.

FIG. 24 is a structural diagram of a power module provided by another embodiment of the present application.

FIG. 25 is a side view of the FIG. 24.

FIG. 26 is an A-A sectional view of the FIG. 25.

FIG. 27 is a B-B sectional view of the FIG. 25.

FIG. 28 is a structural diagram of a power module provided by a still another embodiment of the present application.

FIG. 29 is a side view of the FIG. 28.

FIG. 30 is an A-A sectional view of the FIG. 29.

FIG. 31 is a B-B sectional view of the FIG. 29.

FIG. 32 is a structural diagram of a power module provided by a yet another embodiment of the present application.

FIG. 33 is a side view of the FIG. 32.

FIG. 34 is an A-A sectional view of the FIG. 33.

FIG. 35 is a B-B sectional view of the FIG. 33.

### REFERENCE SIGNS

11—First accommodating space; 12—Second accommodating space; 13—First power device; 14—Second power device; 15—Cover plate; 16—Fan;
100—Insulating board; 101—First side plate; 102—Second side plate; 110—Flat plate section; 120—Protrusion portion; 130—Connecting bridge; 140—Insulation cavity; 141—First insulation cavity; 142—Second insulation cavity; 150—Partition board;
200—Transformer; 201—First endpoint; 202—Second endpoint; 203—Third endpoint; 204—Fourth endpoint; 205—Fifth endpoint; 206—Sixth endpoint; 207—Seventh endpoint; 208—Eighth endpoint; 210—Magnetic core; 211—First vertical pillar; 212—Second vertical pillar; 213—First transverse pillar; 214—Second transverse pillar; 215—First unit; 216—Second unit; 217—First longitudinal pillar; 218—Second longitudinal pillar; 220—First winding; 221—First part; 222—Second part; 230—Second winding; 231—First part; 232—Second part;
500—First shielding layer; 501—First shielding end; 502—Second shielding end; 503—Third shielding end; 504—Fourth shielding end;
600—Third shielding layer;
X—First direction; Y—Second direction; Z—Third direction.

### DESCRIPTION OF EMBODIMENTS

As described in the BACKGROUND, in related art, the insulating board in the power module is penetrated between the primary side unit and the secondary side unit of the transformer, causing a width of an air gap of the magnetic core of the transformer to be greater than a thickness of the insulating board, resulting in a larger size of the air gap of the magnetic core and reducing the efficiency of the transformer.

In view of this, embodiments of the present application aim to provide a power module, by setting a protrusion portion and a connecting bridge on an insulating board, a protrusion is formed by at least one of the protrusion portion and the connecting bridge to enclose at least one insulation cavity with the insulating board, at least part of the magnetic core of the transformer is set within the insulation cavity or the connecting bridge, so that the flat plate portion of the insulating board does not penetrate through an air gap of the magnetic core, which facilitates a control of a size of the air gap of the magnetic core and is beneficial for improving an efficiency of the transformer in the power module.

To make the purposes, technical solutions and advantages of embodiments of the present application more clearly, the technical solutions in the embodiments of the present application are clearly and completely described in the following with reference to the accompanying drawings of the embodiments of the present application. Obviously, the described embodiments are part of embodiments of the present application, not all embodiments.

Based on the embodiments of the present application, all other embodiments obtained by those skilled in the art without paying creative efforts are all within the protection scope of the present application. In the absence of conflict, the following embodiments and the features in the embodiments may be combined with each other.

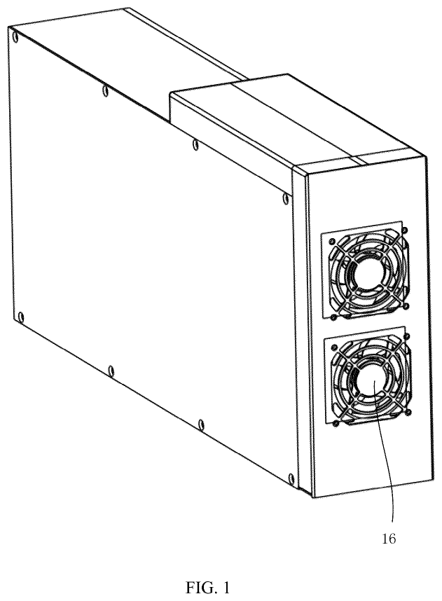

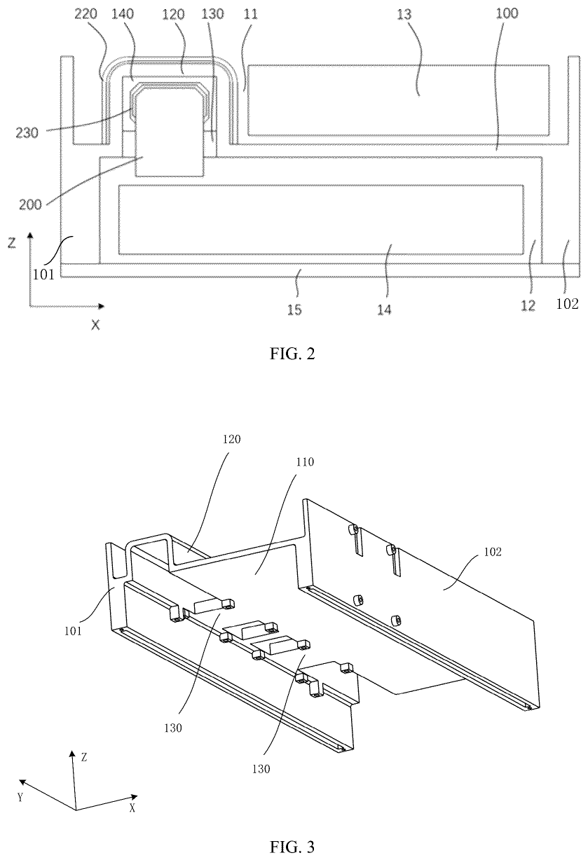

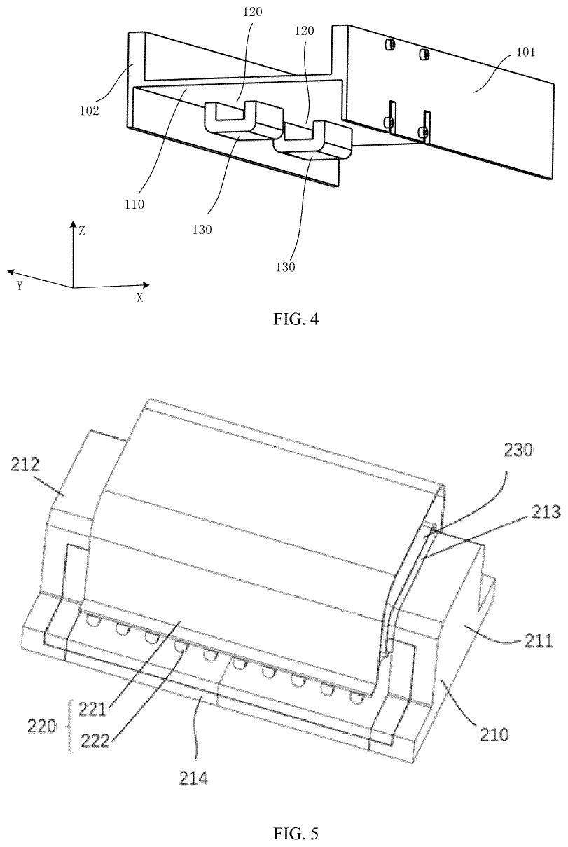

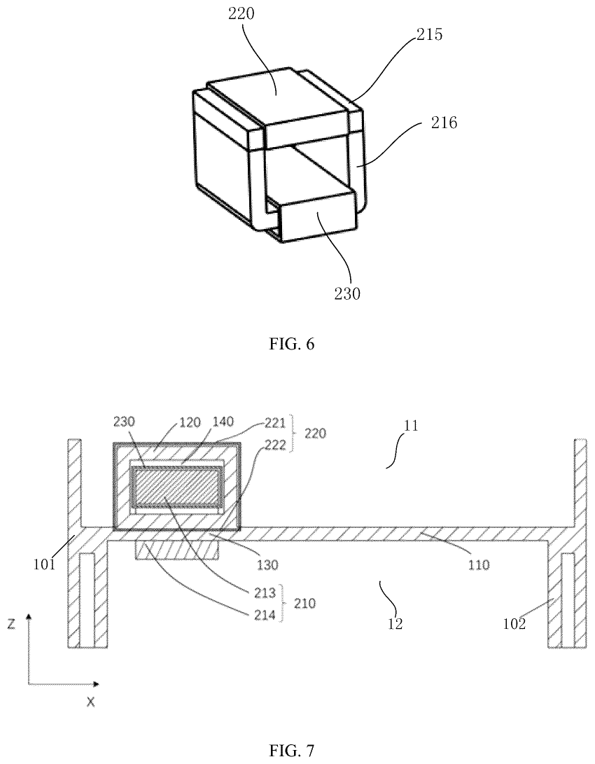

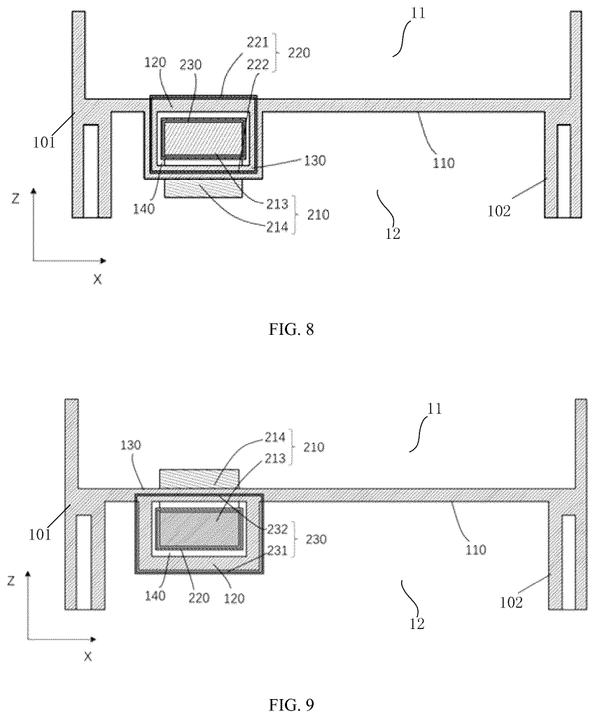

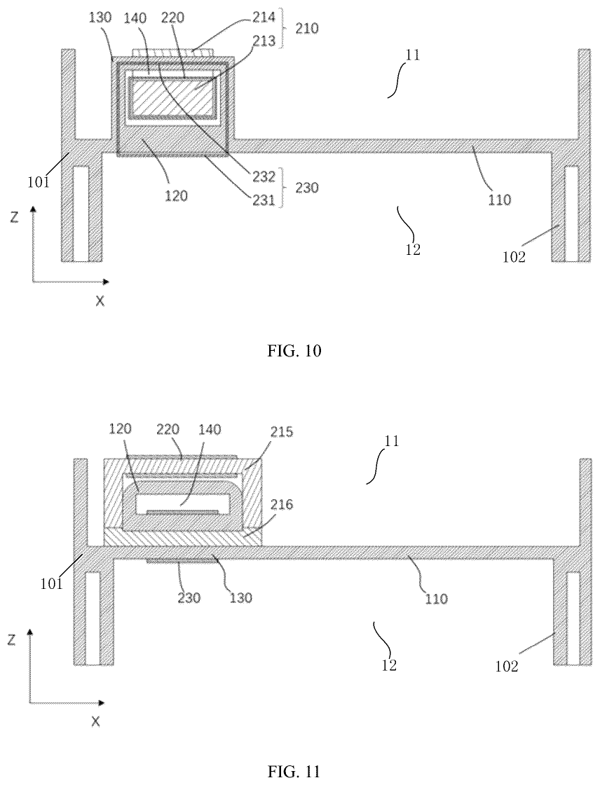

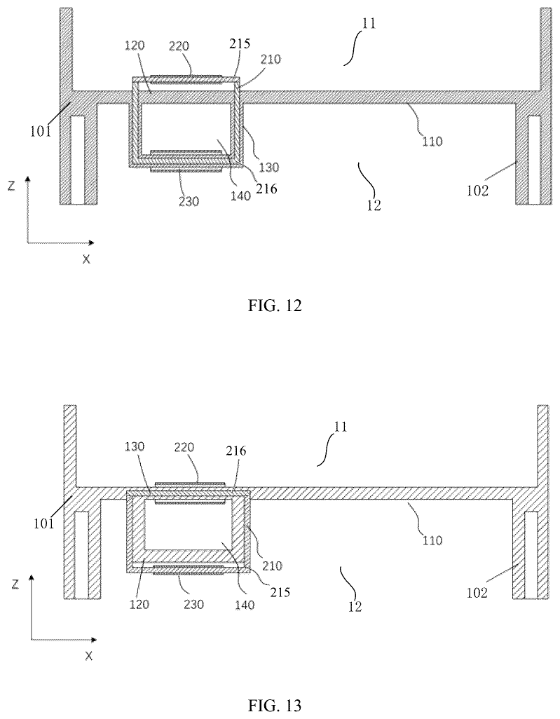

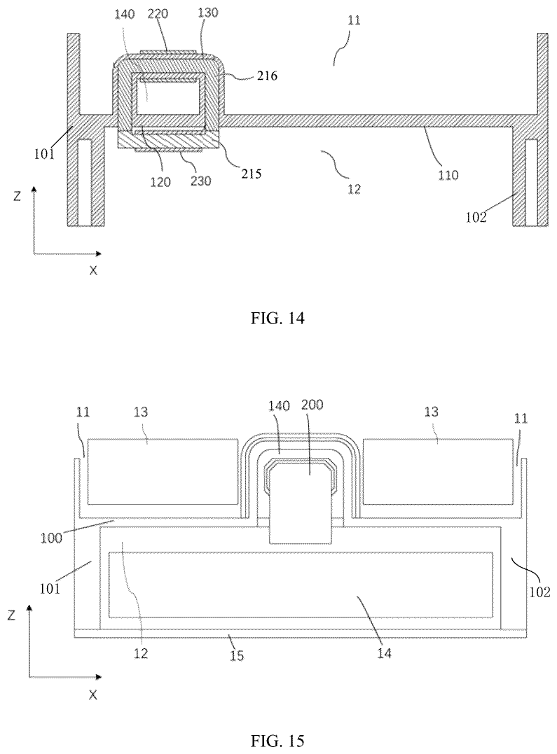

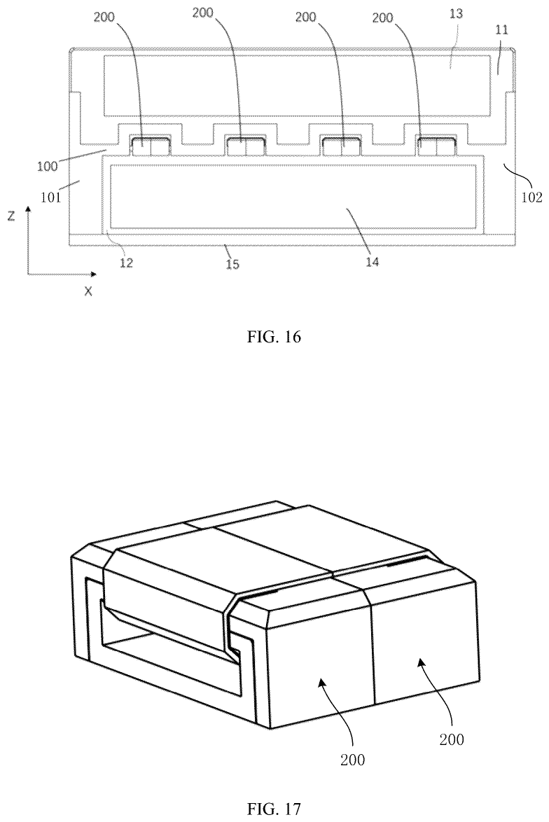

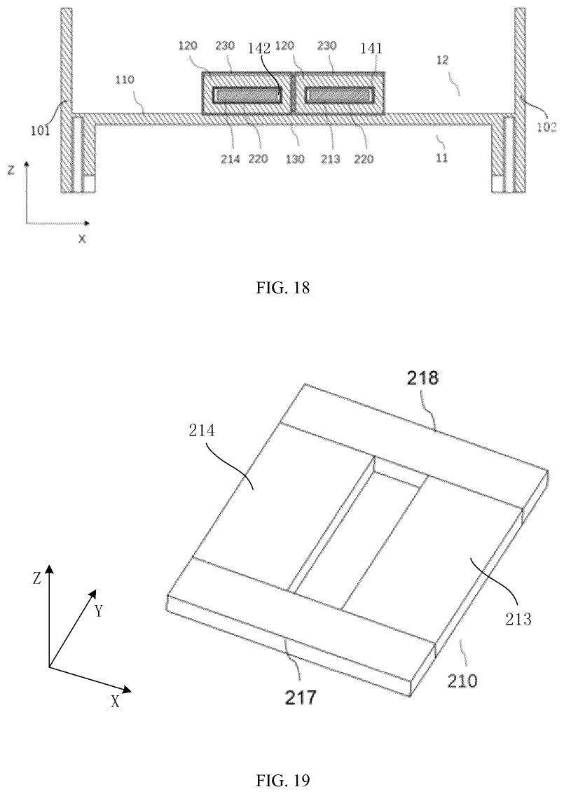

FIG. 1 is an external schematic diagram of a power module provided by an embodiment of the present application; FIG. 2 is a structural diagram of a power module provided by an embodiment of the present application; FIG. 3 is a structural diagram of an insulating board provided by an embodiment of the present application; FIG. 4 is a structural diagram of an insulating board provided by another embodiment of the present application; FIG. 5 is a structural diagram of a transformer provided by an embodiment of the present application; FIG. 6 is a structural diagram of a transformer provided by another embodiment of the present application; FIG. 7 is a schematic diagram of a connection structure of a transformer and an insulating board provided by an embodiment of the present application; FIG. 8 is a schematic diagram of a connection structure of a transformer and an insulating board provided by another embodiment of the present application; FIG. 9 is a schematic diagram of a connection structure of a transformer and an insulating board provided by still another embodiment of the present application; FIG. 10 is a schematic diagram of a connection structure of a transformer and an insulating board provided by yet another embodiment of the present application; FIG. 11 is a schematic diagram of a connection structure of a transformer and an insulating board provided by yet another embodiment of the present application; FIG. 12 is a schematic diagram of a connection structure of a transformer and an insulating board provided by yet another embodiment of the present application; FIG. 13 is a schematic diagram of a connection structure of a transformer and an insulating board provided by yet another embodiment of the present application; FIG. 14 is a schematic diagram of a connection structure of a transformer and an insulating board provided by yet another embodiment of the present application; FIG. 15 is a structural diagram of a power module provided by another embodiment of the present application; FIG. 16 is a structural diagram of a power module provided by still another embodiment of the present application; FIG. 17 is a structural diagram of a transformer provided by still another embodiment of the present application; FIG. 18 is a schematic diagram of a connection structure of a transformer and an insulating board provided by another embodiment of the present application; FIG. 19 is a structural diagram of a magnetic core provided by yet another embodiment of the present application.

It should be noted that in the embodiment, a first direction X, a second direction Y, and a third direction Z are three different directions perpendicular to each other in a three-dimensional space.

Please refer to FIG. 1, FIG. 2, FIG. 15, and FIG. 16, an embodiment provides a power module, which is provided with a first side plate 101, a second side plate 102, and an insulating board 100. In a third direction Z, the insulating board 100, the first side plate 101, and the second side plate 102 in combination form a first accommodating space 11 and a second accommodating space 12; the first accommodating space 11 is provided with a first power device 13 and at least part of a first winding 220, and the second accommodating space 12 is provided with a second power device 14, an insulation cavity 140 is connected to the second accommodating space 12 and has an equal potential, a second winding 230 is set within the insulation cavity 140. The first power device 13 may be, for example, a low-voltage power device, the second power device 14 may be, for example, a high-voltage power device, the first winding 220 may be a low-voltage winding, and the second winding 230 may be a high-voltage winding. The first side plate 101 and the second side plate 102 may be a single-layer structure or a double-layer structure. For example, when the first power device 13 is a low-voltage power device and the second power device 14 is a high-voltage power device, sides of the first side plate 101 and the second side plate 102 located on one side of the first accommodating space may each have a single-layer structure, and sides of the first side plate 101 and the second side plate 102 located on one side of the second accommodating space may each have a double-layer structure. In terms of production manner, the first side plate 101, the second side plate 102, and the insulating board 100 may be integrally-formed, or may be separately produced and assembled. A volume will be smaller for the integrally-formed case, so a volume of the power module may be reduced and a power density may be increased.

In an embodiment, as shown in FIG. 2 and FIG. 15, the power module also includes a cover plate 15. In the third direction Z, the cover plate 15 covers the second accommodating space 12 to form a relatively sealed structure, thereby improving a safety during use. In an embodiment, the power module may also include another cover plate to cover the first accommodating space 11 in the third direction Z. In other possible implementations, the first power device 13 may be a high-voltage power device, the second power device 14 may be a low-voltage power device, the first winding 220 may be a high-voltage winding, and the second winding 230 may be a low-voltage winding. In the third direction Z, the cover plate covers the first accommodating space 11 so as to make the first accommodating space form a relatively sealed structure, thereby improving the safety during use.

Please refer to FIG. 2, FIG. 3, and FIG. 4. In the embodiment, the insulating board 100 includes a flat plate portion 110, a protrusion portion 120, and a connecting bridge 130. Depending on actual application requirements, the insulating board 100 may include multiple protrusion portions 120 and multiple connecting bridges 130. The flat plate portion 110 is parallel to a plane formed by the first direction X and the second direction Y, and at least one of the protrusion portion 120 and the connecting bridge 130 protrude(s) along the third direction Z to jointly form an insulation cavity 140. The number of insulation cavities 140 may also be increased according to actual requirements. At least one of the protrusion portion 120 and the connecting bridge 130 in the embodiment may protrude along the third direction Z in a positive or negative direction (where the positive direction may be a direction indicated by an arrow in the figure, and the negative direction is opposite to the positive direction) relative to the flat plate portion 110. That is, as shown in FIG. 2 or FIG. 3, only the protrusion portion 120 protrudes while the connecting bridge 130 does not protrude to form an insulation cavity 140; or as shown in FIG. 4, only the connecting bridge 130 protrudes while the protrusion portion 120 does not protrude to form an insulation cavity 140; or both the protrusion portion 120 and the connecting bridge 130 protrude to form an insulation cavity 140; in practical application processes, a manner of forming the insulation cavity 140 may be selected as required. It should be noted that the protrusion portion 120 may also be integrated into the flat plate portion 110 as a whole, and protrusion is not a necessary requirement for the protrusion portion 120.

In the embodiment, along the second direction Y, both ends of the insulation cavity 140 are provided with openings to form a heat dissipation air duct, so air would be pulled through the heat dissipation air duct to cool the transformer 200.

For convenience of explanation, referring to FIG. 2, take the direction from the second accommodating space 12 to the first accommodating space 11 as the positive direction of the third direction Z, along the positive direction of the third direction Z, a position relationship between the protrusion portion 120 and the connecting bridge 130 may be the following two types: one is that the protrusion portion 120 is above the connecting bridge 130, and another is that the connecting bridge 130 is above the protrusion portion 120.

For example, in a possible implementation, as shown in FIG. 3, along the third direction Z, a distance between the connecting bridge 130 and the flat plate portion 110 is zero, that is, a bottom surface of the connecting bridge is flush with a bottom surface of the flat plate portion, and the protrusion portion 120 is set to protrude, at one side thereof, towards the first accommodating space 11. That is, in this implementation, the protrusion portion 120 may protrude towards the first accommodating space 11, while the connecting bridge 130 does not protrude, and the connecting bridge 130 and the flat plate portion 110 are both parallel to a plane formed by the first direction X and the second direction Y.

In other possible implementations, along the third direction Z, the distance between the connecting bridge 130 and the flat plate portion 110 is zero, and the protrusion portion 120 may also be set to protrude, at one side thereof, towards the second accommodating space 12. That is, in this implementation, the protrusion portion 120 may protrude towards the second accommodating space 12, while the connecting bridge 130 does not protrude, and the connecting bridge 130 and the flat plate portion 110 are both parallel to a plane formed by the first direction X and the second direction Y.

For example, in another possible implementation, as shown in FIG. 4, along the third direction Z, the distance between the protrusion portion 120 and the flat plate portion 110 is zero, and the connecting bridge 130 is set to protrude, at one side thereof, towards the second accommodating space 12. That is, in this implementation, the connecting bridge 130 may protrude towards the second accommodating space 12, while the protrusion portion 120 does not protrude, and the protrusion portion 120 and the flat plate portion 110 are both parallel to a plane formed by the first direction X and the second direction Y. At this time, the protrusion portion 120 and the flat plate portion 110 may be integrally-formed.

In other possible implementations, along the third direction Z, the distance between the protrusion portion 120 and the flat plate portion 110 is zero, and the connecting bridge 130 is set to protrude, at one side thereof, towards the first accommodating space 11. That is, in this implementation, the connecting bridge 130 may protrude towards the first accommodating space 11, while the protrusion portion 120 does not protrude, and the protrusion portion 120 and the flat plate portion 110 are both parallel to a plane formed by the first direction X and the second direction Y. At this time, the protrusion portion 120 and the flat plate portion 110 may be integrally-formed.

Please refer to FIG. 2, FIG. 5, and FIG. 6. In this embodiment, the power module further includes a transformer 200, which includes a magnetic core 210 and a winding wound on the magnetic core 210. The winding may be directly wound on the magnetic core 210 or indirectly wound on the magnetic core 210. The winding includes a first winding 220 and a second winding 230. The first winding 220 is electrically connected to a first power device 13, and the second winding 230 is electrically connected to a second power device 14. The transformer 200 may achieve a voltage conversion on both sides of the first power device 13 and the second power device 14.

In traditional power module structures, a size of an air gap of the magnetic core may generally only be adjusted in a thickness direction of an insulating board, that is, may be adjusted in the third direction Z, but due to limitations of the insulating board and an internal space, the air gap of the magnetic core cannot be flexibly adjusted, so that an overall design is limited. In this embodiment, at least part of the magnetic core 210 is set within the insulation cavity 140 or the connecting bridge 130, so that the air gap of the magnetic core may be adjusted on three directions: the first direction X, the second direction Y, and the third direction Z. The size of the air gap of the magnetic core may be freely adjusted according to electrical parameter requirements of the transformer 200, which greatly increases a flexibility in designing the magnetic core, and facilitates a control of a size and a tolerance of the air gap of the magnetic core, and an inductance value of the magnetic core, and beneficial for improving the efficiency of the transformer 200 in the power module. In addition, the setting of protrusion with respect to the protrusion portion 120 or the connecting bridge 130 on the flat plate portion 110 enables the insulating board 100 to form a bending structure, which is beneficial for improving an overall strength of the insulating board 100, so that a thinner insulating board 100 may meet the requirements, which is beneficial for reducing an overall weight of the power module.

In a possible implementation, the magnetic core 210 of this embodiment may be penetrated into the insulation cavity 140; that is, at least part of the magnetic core 210 is located within the insulation cavity 140. Part of the winding is set within the connecting bridge 130. The magnetic core 210 is provided with an opening along the first direction X, and the connecting bridge 130 is penetrated into the opening of the magnetic core 210. Referring to FIG. 5, FIG. 7, FIG. 8, FIG. 9, and FIG. 10, the magnetic core 210 includes a first vertical pillar 211 and a second vertical pillar 212 extending along the third direction Z, as well as a first transverse pillar 213 and a second transverse pillar 214 extending along the second direction Y. The first vertical pillar 211, the second vertical pillar 212, the first transverse pillar 213, and the second transverse pillar 214 in combination form an opening towards the first direction X, and the connecting bridge 130 is located between the first transverse pillar 213 and the second transverse pillar 214, the first transverse pillar 213 is located within the insulation cavity 140 formed by a combination of the connecting bridge 130 and the protrusion portion 120.

One of the first winding 220 or the second winding 230 in this embodiment may be directly wound on the magnetic core 210, and the other winding includes a first part and a second part interconnected. The first part is located on one side of the protrusion portion 120 away from the insulation cavity 140, and the second part is located within the connecting bridge 130. In an embodiment, the protrusion portion 120 may be of a hollow structure, and the first part of the other winding penetrates through a hollow portion of the protrusion portion 120; the protrusion portion 120 may also be of a solid structure, and the first part of the other winding is set within the protrusion portion 120 and is integrally-formed with the protrusion portion 120; or, an open groove is set on a surface of the side of the protrusion portion 120 away from the insulation cavity 140, and the first part of the other winding is set within the groove, the first part of the other winding is integrally-formed or independently set with the protrusion portion 120; or, the side of the protrusion portion 120 away from the insulation cavity 140 is set smoothly, without setting a groove, and the first part of the other winding is set on the surface of the side of the protrusion portion 120 away from the insulation cavity 140.

As shown in FIG. 7, in one embodiment, the protrusion portion 120 protrudes, at one side thereof, towards the first accommodating space 11, the connecting bridge 130 and the flat plate portion 110 are located within a same horizontal plane, the first transverse pillar 213 of the magnetic core 210 penetrates into the insulation cavity 140 enclosed by the protrusion portion 120 and the connecting bridge 130, and the connecting bridge 130 penetrates between the first transverse pillar 213 and the second transverse pillar 214 of the magnetic core 210. The second winding 230 is directly wound on the first transverse pillar 213; the first winding 220 includes two electrically connected parts, the first part 221 of the first winding 220 is set on the outside of the protrusion portion 120, and the second part 222 of the first winding 220 is set within the connecting bridge 130. In this embodiment, reference may be made to the structure shown in FIG. 5 for a winding manner of the windings. The first winding 220 includes the first part 221 and the second part 222, the first part 221 is located on the side of the protrusion portion 120 away from the insulation cavity 140, and the second part 222 is located within the connecting bridge 130. The second winding 230 is directly wound on the magnetic core 210, and the insulation cavity 140 is connected to the second accommodating space 12 and they have an equal potential.

In an embodiment, the first part 221 and the second part 222 of the first winding 220 may be integrally-formed, at this time, a through-hole is set within the connecting bridge 130 (i.e., the through-hole penetrates through an inside of the connecting bridge 130), the second part 222 is located within the through-hole.

Alternatively, the second part 222 may be integrally-formed with the connecting bridge 130. For example, the second part 222 may be directly embedded within the connecting bridge 130 during production. An end of the second part 222 is located outside the connecting bridge 130, and an end of the first part 221 is electrically connected to the end of the second part 222. Specifically, the end of the first part 221 may be electrically connected to the end of the second part 222 through welding or in other manners.

As shown in FIG. 8, in one embodiment, the protrusion portion 120 and the flat plate portion 110 are located within the same horizontal plane, and the connecting bridge 130 protrudes, at one side thereof, towards the second accommodating space 12, the first transverse pillar 213 of the magnetic core 210 penetrates into the insulation cavity 140 enclosed by the protrusion portion 120 and the connecting bridge 130. In this embodiment, the connecting bridge 130 is U-shaped, and part of the connecting bridge 130 penetrates between the first transverse pillar 213 and the second transverse pillar 214 of the magnetic core 210. In this embodiment, the second winding 230 is directly wound on the magnetic core 210, in an implementation, directly wound on the first transverse pillar 213; the first winding 220 includes two electrically connected parts, the first part 221 of the first winding 220 is set on the outside of the protrusion portion 120, the second part 222 of the first winding 220 is set within the connecting bridge 130, and the insulation cavity 140 is connected to the second accommodating space 12.

As shown in FIG. 9, in one embodiment, the protrusion portion 120 protrudes, at one side thereof, towards the second accommodating space 12, the connecting bridge 130 and the flat plate portion 110 are located within the same horizontal plane, the first transverse pillar 213 of the magnetic core 210 penetrates into the insulation cavity 140 enclosed by the protrusion portion 120 and the connecting bridge 130, and the connecting bridge 130 penetrates between the first transverse pillar 213 and the second transverse pillar 214 of the magnetic core 210. In this embodiment, the first winding 220 is directly wound on the magnetic core 210, in an implementation, directly wound on the first transverse pillar 213; the second winding 230 includes two electrically connected parts, the first part 231 of the second winding 230 is set on the outside of the protrusion portion 120, and the second part 232 of the second winding 230 is set within the connecting bridge 130, the insulation cavity 140 is connected to the first accommodating space 11.

As shown in FIG. 10, in one embodiment, the protrusion portion 120 and the flat plate portion 110 are located within the same horizontal plane, and the connecting bridge 130 protrudes, at one side thereof, towards the first accommodating space 11, the first transverse pillar 213 of the magnetic core 210 penetrates into the insulation cavity 140 enclosed by the protrusion portion 120 and the connecting bridge 130. In this embodiment, the connecting bridge 130 is U-shaped, and part of the connecting bridge 130 penetrates between the first transverse pillar 213 and the second transverse pillar 214 of the magnetic core 210. In this embodiment, the first winding 220 is directly wound on the magnetic core 210, in an implementation, directly wound on the first transverse pillar 213; the second winding 230 includes two electrically connected parts, the first part 231 of the second winding 230 is set on the outside of the protrusion portion 120, the second part 232 of the second winding 230 is set within the connecting bridge 130, and the insulation cavity 140 is connected to the first accommodating space 11.

In the embodiments shown in FIG. 7, FIG. 8, FIG. 9, and FIG. 10, the insulation cavity 140 is provided with an opening in the second direction Y. Referring to FIG. 1 and FIG. 3, an airflow generated by a fan 16 may pass along the second direction Y, heat generated by the transformer arranged in the insulation cavity 140 may be directly carried away by the airflow, a heat dissipation efficiency is greatly improved, which is beneficial for reducing a volume of the power module and increasing a power density.

In another possible implementation, the connecting bridge 130 is provided with a through-hole in the first direction X, and the magnetic core 210 may be penetrated into the connecting bridge 130; that is, at least part of the magnetic core 210 is located within the connecting bridge 130. Referring to FIG. 6, FIG. 11, FIG. 12, FIG. 13, and FIG. 14, the magnetic core 210 includes a first unit 215 and a second unit 216. The first unit 215 is located on one side of the protrusion portion 120 away from the insulation cavity 140, and the second unit 216 is fully or partially penetrated into the connecting bridge 130, the second unit 216 may be integrally-formed with the connecting bridge 130. In an embodiment, the protrusion portion 120 may be of a hollow structure, and the second unit 216 penetrates through a hollow portion of the protrusion portion 120; the protrusion portion 120 may also be of a solid structure, the second unit 216 is set within the protrusion portion 120 and is integrally-formed with the protrusion portion 120; an open groove is provided on a surface of the protrusion portion 120 away from the insulation cavity 140, and the second unit 216 is set within the groove, the second unit 216 is independently set or integrally-formed with the protrusion portion 120; or, the side of the protrusion portion 120 away from the insulation cavity 140 is set smoothly, without setting a groove, and the second unit 216 is set on the surface of the protrusion portion 120 away from the insulation cavity 140. In an embodiment, the magnetic core 210 may only include the second unit 216 that penetrates into the connecting bridge, which is an I-type magnetic core, and there is no magnetic core 210 outside the protrusion portion 120. In this implementation, based on the different structures of the protrusion portion 120 and the connecting bridge 130, the following embodiments can be included.

As shown in FIG. 11, in one embodiment, the protrusion portion 120 protrudes, at one side thereof, towards the first accommodating space 11, and the connecting bridge 130 and the flat plate portion 110 are located within the same horizontal plane. The magnetic core 210 includes the first unit 215 and the second unit 216, and the first unit 215 and the second unit 216 may be in direct contact or have a certain gap there between in the third direction Z. The first unit 215 is U-shaped and covers the outside of the protrusion portion 120, while the second unit 216 is roughly strip-shaped in the first direction X and is set within the connecting bridge 130. Another feasible manner not shown in FIG. 11 is that the first unit 215 of the magnetic core 210 is located on the outside of the protrusion portion 120, and the second unit 216 is U-shaped and partially penetrated into the connecting bridge 130. The second unit 216 may be integrally-formed with the connecting bridge 130. The first winding 220 is wound on the first unit 215 of the magnetic core 210, the first winding 220 may be wound on at least one of a transverse pillar and vertical pillars of the first unit 215, or the first winding 220 may be wound on the second unit 216 of the magnetic core 210 set within the connecting bridge 130. The second winding 230 is wound on the connecting bridge 130, and the insulation cavity 140 is connected to the second accommodating space 12.

As shown in FIG. 12, in one embodiment, the protrusion portion 120 and the flat plate portion 110 are located within the same horizontal plane, and the connecting bridge 130 protrudes, at one side thereof, towards the second accommodating space 12. The magnetic core 210 includes the first unit 215 and the second unit 216, the first unit 215 and the second unit 216 may be in direct contact or have a certain gap there between in the third direction Z. The first unit 215 of the magnetic core 210 is located on the outside of the protrusion portion 120, and the second unit 216 of the magnetic core 210 is U-shaped and penetrated into the connecting bridge 130. Another feasible manner not shown in FIG. 12 is that the first unit 215 is also U-shaped, and a part of the first unit 215 is located on the outside of the protrusion portion 120 and another part is penetrated into the connecting bridge 130 along the third direction Z. At this time, the second unit 216 may be U-shaped or may be strip-shaped in the first direction X. The second unit 216 may be integrally-formed with the connecting bridge 130. The first winding 220 located within the first accommodating space 11 is wound on the first unit 215 of the magnetic core 210 outside the protrusion portion 120, the second winding 230 is wound on the connecting bridge 130, and the second winding 230 is partially located in the second accommodating space 12 and partially located in the insulation cavity 140, the insulation cavity 140 is connected to the second accommodating space 12, which can be understood as the second winding 230 being fully located within the second accommodating space 12. Specifically, the second winding 230 may be wound around at least one of a horizontal portion and vertical portions of the connecting bridge 130.

As shown in FIG. 13, in one embodiment, the protrusion portion 120 protrudes, at one side thereof, towards the second accommodating space 12, and the connecting bridge 130 and the flat plate portion 110 are located within the same horizontal plane. The magnetic core 210 includes the first unit 215 and the second unit 216, the first unit 215 and the second unit 216 may be in direct contact or have a certain gap there between in the third direction Z. The first unit 215 is U-shaped and covers the outside of the protrusion portion 120, while the second unit 216 is roughly strip-shaped in the first direction X and is fully located within the connecting bridge 130. Another feasible manner not shown in FIG. 13 is that the first unit 215 of the magnetic core 210 is located on the outside of the protrusion portion 120, and the second unit 216 is U-shaped and partially penetrated into the connecting bridge 130. The second unit 216 may be integrally-formed with the connecting bridge 130. The first winding 220 is wound on the connecting bridge 130, and the first winding 220 is partially located within the first accommodating space 11, and partially in the insulation cavity 140, the insulation cavity 140 is connected to the first accommodating space 11, which may be understood as the first winding 220 being fully located within the first accommodating space 11, and the second winding 230 located within the second accommodating space 12 being wound on the magnetic core 210 outside the protrusion portion 120.

As shown in FIG. 14, in one embodiment, the protrusion portion 120 and the flat plate portion 110 are located within the same horizontal plane, and the connecting bridge 130 protrudes, at one side thereof, towards the first accommodating space 11. The magnetic core 210 includes the first unit 215 and the second unit 216, the first unit 215 and the second unit 216 may be in direct contact or have a certain gap there between in the third direction Z. The first unit 215 of the magnetic core 210 is located on the outside of the protrusion portion 120, and the second unit 216 of the magnetic core 210 is U-shaped and penetrated into the connecting bridge 130. Another feasible manner not shown in FIG. 14 is that the first unit 215 is U-shaped, a part of the first unit 215 is located on the outside of the protrusion portion 120, and another part is penetrated into the connecting bridge 130 along the third direction Z. At this time, the second unit 216 may be U-shaped or may be strip-shaped in the first direction X. The second unit 216 may be integrally-formed with the connecting bridge 130. The first winding 220 is wound on the connecting bridge 130, and the first winding 220 is partially located within the first accommodating space 11 and partially in the insulation cavity 140, the insulation cavity 140 is connected to the first accommodating space 11, which can be understood as the first winding 220 being fully located within the first accommodating space 11, and the second winding 230 located within the second accommodating space 12 being wound on the magnetic core 210 outside the protrusion portion 120.

In the embodiments shown in FIG. 11 to FIG. 14, by setting the winding outside the insulation cavity 140, the winding is not insulated, which is more conducive to a heat dissipation. Since a loss of the winding of the transformer is greater than a loss of the magnetic core, setting the winding outside the insulation cavity 140 may further improve the efficiency of the transformer 200. In addition, in the embodiment, the winding does not need to penetrate through an interior of the connecting bridge 130, and a connection of incoming and outgoing lines is simple; and at this time, a smooth air duct may be formed within the insulation cavity 140 in the second direction Y, which is more beneficial to the heat dissipation.

The surface of the insulating board 100 disclosed in the embodiment may be provided with a semi conductive layer, and materials of the semi conductive layer may include a graphene or a carbon black for shielding and other purposes. Common parameters for semi conductive coatings would include a thickness (10 um˜200 um), a conductivity range (10\hat{ }(−11) s/m˜10\hat{ }(3) s/m), but not limited thereto.

The insulation cavity 140 disclosed in the embodiment has openings at both ends along the second direction Y, that is, the interior of the insulation cavity 140 is conductive in the second direction Y, thus enabling the airflow generated by the fan 16 to directly act on the transformer 200, to directly take away the heat generated by the transformer 200, thereby greatly improving the efficiency of the heat dissipation, as well as reducing the volume of the power module, and increasing the power density.

In another embodiment, the power module may also have a structure as shown in FIG. 15, that is, along the first direction X, the insulation cavity 140 is located at a middle of the insulating board 100, and the corresponding transformer 200 is also located at the middle of the insulating board 100.

By adopting the above structure, the first accommodating space 11 may be distributed on both sides of the insulation cavity 140. Compared with the structure shown in FIG. 2, where the insulation cavity 140 is set near an edge of the insulating board 100, the structure shown in FIG. 15 is more advantageous for an arrangement of the first power device 13 in a limited space, which greatly improves space utilization, is beneficial for reducing the volume of the power module, and increment of the power density.

In another embodiment, the power module may also have a structure as shown in FIG. 16, the insulating board 100 may be provided with multiple insulation cavities 140. At this time, the power module includes multiple transformers 200, and multiple transformers 200 correspond to multiple insulation cavities 140, according to different circuit structures, at least one transformer 200 may also be placed in one insulation cavity. In this embodiment, multiple transformers 200 may be connected in series or parallel. As shown in FIG. 17, in this embodiment, two transformers 200 connected in series are provided in one insulation cavity 140, and transformers 200 in multiple insulation cavities 140 may be connected in parallel with each other.

By adopting the above structure, a size of a single transformer 200 may be reduced, and a height of the insulation cavity 140 may be reduced, so that the first power device 13 and the second power device 14 may be closer to the transformer 200, which is beneficial for saving space, reducing the volume of the power module, and increasing the power density.

In another embodiment, the magnetic core 210 is provided with a through-hole along the third direction Z, and at this time, the insulating board 100 includes multiple protrusion portions 120 and multiple connecting bridges 130, the multiple protrusion portions 120 and multiple connecting bridges 130 in combination form multiple insulation cavities 140. As shown in FIG. 18, the insulating board 100 includes at least two insulation cavities 140, taking two insulation cavities 140 as an example, they are a first insulation cavity 141 and a second insulation cavity 142 respectively, both of them are provided with magnetic cores 210. Referring to FIG. 19, the magnetic core 210 includes a first longitudinal pillar 217 and a second longitudinal pillar 218 extending along the first direction X, as well as a first transverse pillar 213 and a second transverse pillar 214 extending along the second direction Y. The combination of the first longitudinal pillar 217, the second longitudinal pillar 218, the first transverse pillar 213, and the second transverse pillar 214 forms an opening towards the third direction Z. The first winding 220 is set within the insulation cavity 140, the second winding 230 is partially set within the connecting bridge 130, and partially set within the second accommodating space 12.

The protrusion portion 120 protrudes, at one side thereof, towards the second accommodating space 12, and the connecting bridge 130 and the flat plate portion 110 are located within the same horizontal plane. The first transverse pillar 213 and the second transverse pillar 214 of the magnetic core 210 are respectively penetrated into the first insulation cavity 141 and the second insulation cavity 142. In this embodiment, the number of windings is not limited, for example, there are two first windings 220 and two second windings 230, the two first windings 220 are directly wound on the first transverse pillar 213 and the second transverse pillar 214 respectively; the two second windings 230 both include two electrically connected parts, the first parts 231 of the two second windings 230 are respectively set on the outsides of the protrusion portions 120 forming the first insulation cavity 141 and the second insulation cavity 142, the second parts 232 of the two second windings 230 are respectively set within the connecting bridges 130 forming the first insulation cavity 141 and the second insulation cavity 142. That is, the first transverse pillar 213 is wound by the first winding 220 and the second winding 230, the second transverse pillar 214 is also wound by the first winding 220 and the second winding 230. The first winding 220 wound on different transverse pillars may be electrically connected in series or parallel, and the second winding 230 wound on different transverse pillars may be electrically connected in series or parallel. By adopting this structure, a module output assembly is flexible.

Other feasible manners not shown in FIG. 18 include: the protrusion portion 120 and the flat plate portion 110 are located within the same horizontal plane, and the connecting bridge 130 protrudes, at one side thereof, towards the first accommodating space 11; or, the connecting bridge 130 protrudes, at one side thereof, towards the second accommodating space 12, the protrusion portion 120 and the flat plate portion 110 are located within the same horizontal plane; or, the connecting bridge 130 and the flat plate portion 110 are located within the same horizontal plane, and the protrusion portion 120 protrudes, at one side thereof, towards the first accommodating space 11.

As described in the background, in the power module of the related art, air among the magnetic core and the first and second windings undertakes a large electric field. When there are sharp burrs on an edge of the magnetic core, discharge may occur, thereby affecting the insulation life.

In view of this, the embodiments of the present application aim to provide a power module, in which a first shielding layer is provided on one side of the insulating board facing towards the magnetic core, and a projection of the magnetic core is located within a projection range of the first shielding layer, so that the first shielding layer can be used to reduce the electric-field-strength in the air around the magnetic core, prolong insulation life, and improve reliability of the product.

The following will provide a detailed description of the embodiments of the present application in conjunction with the accompanying drawings, in order to enable the person skilled in the art to have a more detailed understanding of the content of the present application. In the description of the embodiments of the present application, a plane formed by the first direction X and the second direction Y is a first reference plane; a plane formed by the first direction X and the third direction Z is a second reference plane; and a plane formed by the second direction Y and the third direction Z is a third reference plane.

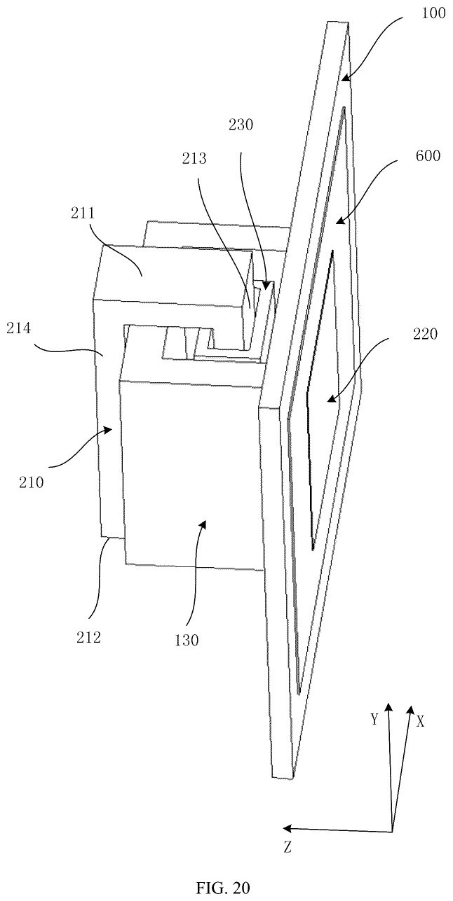

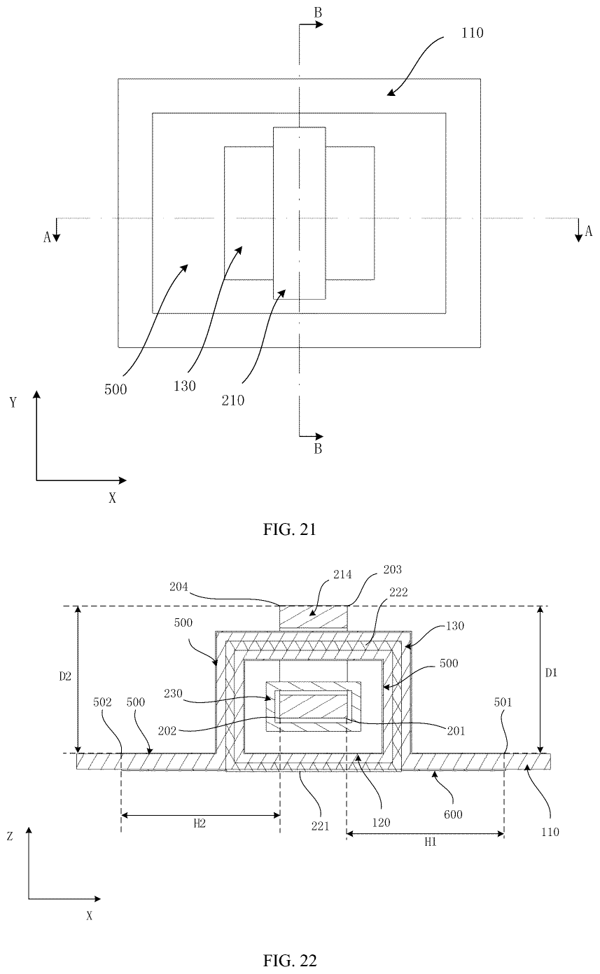

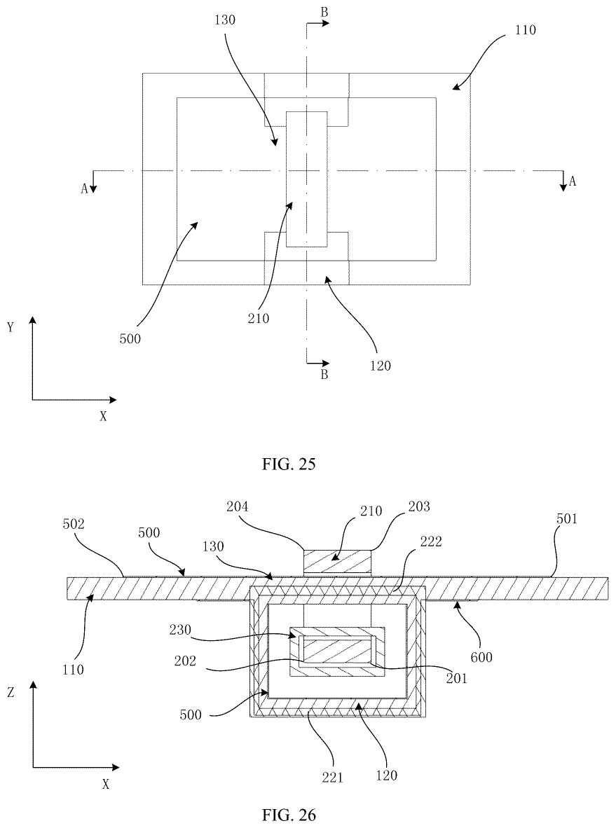

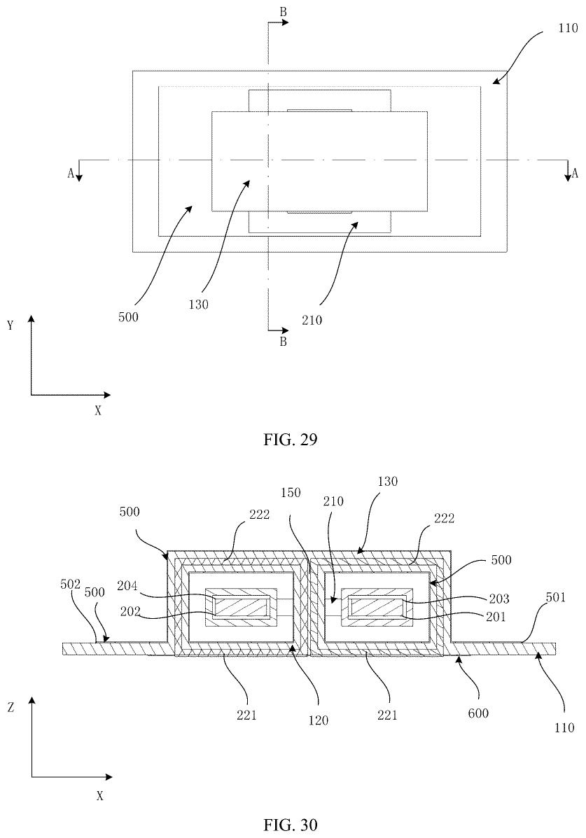

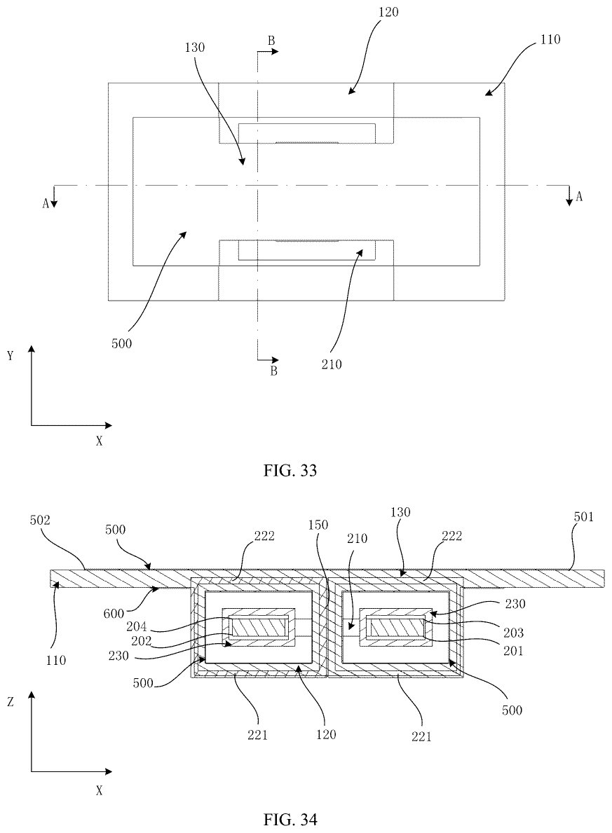

Please refer to FIG. 20 to FIG. 35, the present embodiment provides a power module, including:
an insulating board 100, which can be formed using insulation materials;
a transformer, which includes a magnetic core 210, and at least one first winding 220 and at least one second winding 230 wound around the magnetic core 210. The first winding 220 includes a first part 221 and a second part 222 that are electrically connected to each other. The first part 221 is located on one side of the insulating board 100 away from the magnetic core 210, and the second part 222 is inserted into the insulating board 100. One of the first winding 220 and the second winding 230 is a high-voltage winding, and the other is a low-voltage winding. One side of the insulating board 100 is set with a high-voltage power device, and the other side is set with a low-voltage power device. One of the first winding 220 and the second winding 230 is electrically connected to the high-voltage power device, and the other is electrically connected to the low-voltage power device;
a first shielding layer 500, which is provided on one side of the insulating board 100 facing towards the magnetic core 210. For example, the first shielding layer 500 is a semi conductive layer, and a material of the first shielding layer 500 includes a graphene, a carbon black, a coating doped with conductive particles such as the graphene or the carbon black, or a thin film filled with the conductive particles. In the first reference plane, the projection of the magnetic core 210 is located within the projection range of the first shielding layer 500; that is to say, the entire projection of the magnetic core 210 falls completely within the projection range of the first shielding layer 500, so that the electromagnetic shielding effect against the magnetic core 210 can be achieved by using the first shielding layer 500.

It can be understood that in this embodiment, the first shielding layer 500 is set on one side of the insulating board 100 facing towards the magnetic core 210, and the projection of the magnetic core 210 is located within the projection range of the first shielding layer 500, so that the first shielding layer 500 can be used to reduce the electric-field-strength in the air around the magnetic core 210, prolong the insulation life, and improve the reliability of the product, and also reduce a size of the insulation layer.

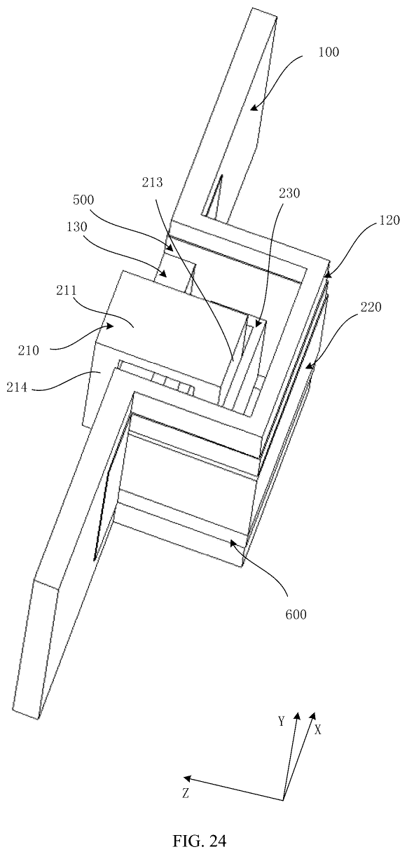

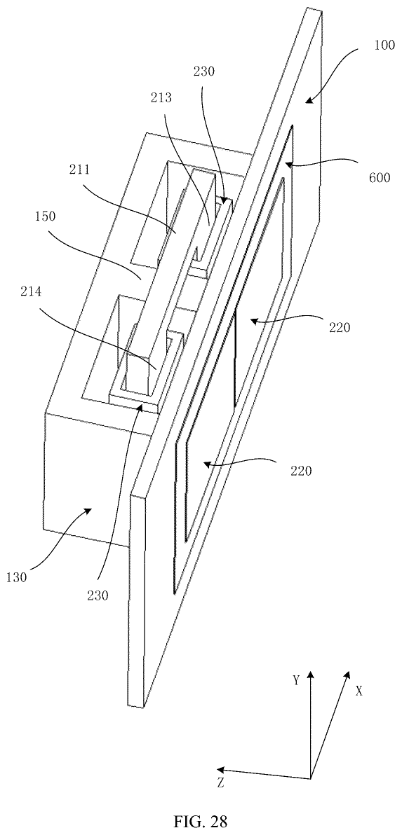

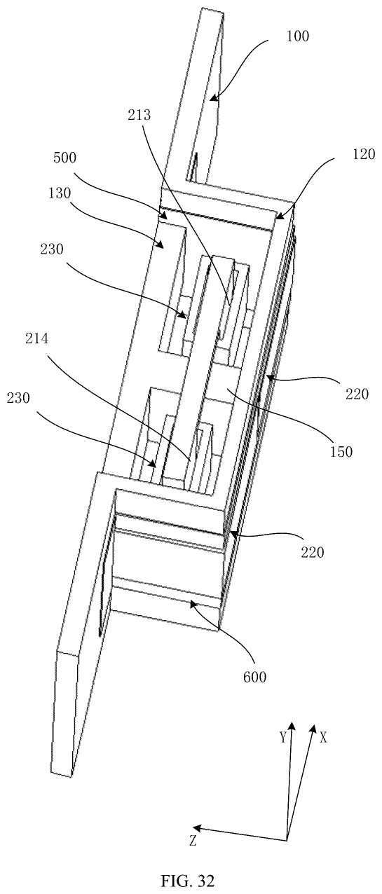

In the present embodiment, the insulating board 100 includes a flat plate portion 110, a protrusion portion 120, and a connecting bridge 130. The flat plate portion 110 is parallel to the first reference plane, and the protrusion portion 120 and/or the connecting bridge 130 protrude from the flat plate portion 110 along the third direction Z, thereby forming an insulation cavity. At least part of the magnetic core 210 is set within the insulation cavity. In the present embodiment, at least one of the protrusion portion 120 and the connecting bridge 130 may protrude relative to the flat plate portion 110. For example, as shown in FIG. 20 and FIG. 28, the connecting bridge 130 protrudes relative to the flat plate portion 110, while the protrusion portion 120 does not protrude and is located in the same plane as the flat plate portion 110. As shown in FIG. 24 and FIG. 32, the protrusion portion 120 protrudes relative to the flat plate portion 110, while the connecting bridge 130 does not protrude and is located in the same plane as the flat plate portion 110. In other possible embodiments, the protrusion portion 120 and the connecting bridge 130 can both protrude relative to the flat plate portion 110. It can be understood that in the present embodiment, the protrusion portion 120 and the connecting bridge 130 only refer to names of two different parts on the insulating board 100, and the text does not represent their specific structure.

Furthermore, the first part 221 of the first winding 220 is located on a surface of the protrusion portion 120 or penetrates within the protrusion portion 120. For example, the first part 221 is located on one side of the insulating board 100 away from the magnetic core 210. At this time, the first part 221 can be located on the surface of the protrusion portion 120, or part of the first part 221 can be buried inside the protrusion portion 120, or the first part 221 can penetrate within the protrusion portion 120. When the first part 221 penetrates within the protrusion portion 120, the structure of the protrusion portion 120 can be the same as that of the connecting bridge 130. The second part 222 is located within the connecting bridge 130; that is to say, the second part 222 penetrates within the connecting bridge 130. The second winding 230 is directly wound on the magnetic core 210. For example, the second winding 230 can be located on the magnetic core 210 inside the insulation cavity, or on the magnetic core 210 outside the insulation cavity.

The magnetic core 210 of the present embodiment includes a first vertical pillar 211 and a second vertical pillar 212 arranged opposite to each other, as well as a first transverse pillar 213 and a second transverse pillar 214 arranged opposite to each other; the first vertical pillar 211, the first transverse pillar 213, the second vertical pillar 212, and second transverse pillar 214 are connected head-to-tail in sequence.

It can be understood that the power module of the present embodiment can be set to different structures according to specific requirements.

In some possible implementations, as shown in FIG. 20 to FIG. 23, along the third direction Z, a distance between the protrusion portion 120 and the flat plate portion 110 is zero, that is, the protrusion portion 120 and the flat plate portion 110 are located in the same plane, and the connecting bridge 130 protrudes from the flat plate portion 110. Along the second direction Y, a height of the first transverse pillar 213 is greater than that of the insulation cavity. The first transverse pillar 213 penetrates through the insulation cavity, with a part of the first transverse pillar 213 located inside the insulation cavity and another part located outside the insulation cavity. The second transverse pillar 214 is located outside the insulation cavity, and the second winding 230 is wound around the first transverse pillar 213.

In some possible implementations, as shown in FIG. 24 to FIG. 27, along the third direction Z, a distance between the connecting bridge 130 and the flat plate portion 110 is zero, that is, the connecting bridge 130 and the flat plate portion 110 are located in the same plane, and the protrusion portion 120 protrudes from the flat plate portion 110. Along the second direction Y, a height of the first transverse pillar 213 is greater than that of the insulation cavity. The first transverse pillar 213 penetrates through the insulation cavity, with a part of the first transverse pillar 213 located inside the insulation cavity and another part located outside the insulation cavity. The second transverse pillar 214 is located outside the insulation cavity, and the second winding 230 is wound around the first transverse pillar 213.

In some possible implementations, as shown in FIG. 28 to FIG. 31, along the third direction Z, a distance between the protrusion portion 120 and the flat plate portion 110 is zero, that is, the protrusion portion 120 and the flat plate portion 110 are located in the same plane, and the connecting bridge 130 protrudes from the flat plate portion 110. The insulating board 100 also includes a partition board 150, which is set inside the insulation cavity. The partition board 150 is connected with the protrusion portion 120 and the connecting bridge 130, and divides the insulation cavity into a first insulation cavity and a second insulation cavity. Along the second direction Y, the height of the first transverse pillar 213 is greater than that of the first insulation cavity, and the height of the second transverse pillar 214 is greater than that of the second insulation cavity. The first transverse pillar 213 penetrates through the first insulation cavity, with a part of the first transverse pillar 213 located inside the first insulation cavity and another part located outside the first insulation cavity. The second transverse pillar 214 penetrates through the second insulation cavity, with a part of the second transverse pillar 214 located inside the second insulation cavity and another part located outside the second insulation cavity.

The transformer includes two first windings 220 and two second windings 230. The two first windings 220 are respectively wound on outer sides of the two second windings 230. The first parts 221 of the two first windings 220 are respectively provided on one side of the protrusion part 120 away from the insulation cavity. The second parts 222 of the two first windings 220 are respectively provided within the partition board 150 and the connecting bridge 130. The two second windings 230 are respectively provided in the first and second insulation cavities and wound on the first transverse pillar 213 and the second transverse pillar 214.

Compared with the implementations shown in FIG. 20 to FIG. 23, the present implementation can fully utilize the structure of the magnetic core 210, which is beneficial for improving power density of the power module and enabling the power module to meet the demand for higher power.

In one possible implementation, as shown in FIG. 32 to FIG. 35, along the third direction Z, the distance between the connecting bridge 130 and the flat plate portion 110 is zero, that is, the connecting bridge 130 and the flat plate portion 110 are located in the same plane, and the protrusion portion 120 protrudes from the flat plate portion 110. The insulating board 100 also includes a partition board 150, which is set inside the insulation cavity. The partition board 150 is connected with the protrusion portion 120 and the connecting bridge 130, and divides the insulation cavity into a first insulation cavity and a second insulation cavity. Along the second direction Y, the height of the first transverse pillar 213 is greater than that of the first insulation cavity, and the height of the second transverse pillar 214 is greater than that of the second insulation cavity. The first transverse pillar 213 penetrates through the first insulation cavity, with a part of the first transverse pillar 213 located inside the first insulation cavity and another part located outside the first insulation cavity. The second transverse pillar 214 penetrates through the second insulation cavity, with a part of the second transverse pillar 214 located inside the second insulation cavity and another part located outside the second insulation cavity.

The transformer includes two first windings 220 and two second windings 230. The two first windings 220 are respectively wound on outer sides of the two second windings 230. The first parts 221 of the two first windings 220 are respectively provided on one side of the protrusion part 120 away from the insulation cavity. The second parts 222 of the two first windings 220 are respectively provided within the partition board 150 and the connecting bridge 130. The two second windings 230 are respectively provided in the first and second insulation cavities and wound on the first transverse pillar 213 and second transverse pillar 214.

Compared with the implementations shown in FIG. 24 to FIG. 27, the present implementation can fully utilize the structure of the magnetic core 210, which is beneficial for improving power density of the power module and enabling the power module to meet the demand for higher power.

In traditional power module structures, a size of an air gap of the magnetic core may generally only be adjusted in a thickness direction of the insulating board, that is, in the third direction Z, but due to limitations of the insulating board and an internal space, the air gap of the magnetic core cannot be flexibly adjusted, so that an overall design is limited. In the present embodiment, at least part of the magnetic core 210 is set within the insulation cavity, so that the air gap of the magnetic core may be adjusted on three directions: the first direction X, the second direction Y, and the third direction Z. The size of the air gap of the magnetic core may be freely adjusted according to electrical parameter requirements of the transformer, which greatly increases a flexibility in designing the magnetic core, and facilitates a control of a size and a tolerance of the air gap of the magnetic core, and an inductance value of the magnetic core, and is beneficial for improving the efficiency of the transformer in the power module. In addition, the protrusion portion 120 or the connecting bridge 130 provided on the flat plate portion 110 enables the insulating board 100 to form a bending structure, which is beneficial for improving an overall strength of the insulating board 100, so that a thinner insulating board 100 may meet the requirements, which is beneficial for reducing an overall weight of the power module.

Please continue to refer to FIG. 22, FIG. 26, FIG. 30, and FIG. 34. When within a plane parallel to the second reference plane, which penetrates through the magnetic core 210 and the insulating board 100, in a cross-sectional view corresponding to the magnetic core 210 and the insulating board 100, the magnetic core 210 includes a first endpoint 201, a second endpoint 202, a third endpoint 203, and a fourth endpoint 204. That is, the first endpoint 201, the second endpoint 202, the third endpoint 203, and the fourth endpoint 204 are the four vertices of the magnetic core 210 in this plane, respectively.

Along the third direction Z, the first endpoint 201 and the second endpoint 202 are located at two ends of the magnetic core 210 near the protrusion portion 120, respectively. The third endpoint 203 and the fourth endpoint 204 are located at two ends of the magnetic core 210 away from the protrusion portion 120, respectively, that is, the third endpoint 203 is located on one side of the first endpoint 201 away from the protrusion portion 120, and the fourth endpoint 204 is located on one side of the second endpoint 202 away from the protrusion portion 120. It should be noted that in the implementation shown in FIG. 26, since a part of the magnetic core 210 is located inside the insulation cavity in the plane formed by the first direction X and the third direction Z, the first endpoint 201 and the second endpoint 202 are two endpoints of the magnetic core 210 located inside the insulation cavity, while the third endpoint 203 and the fourth endpoint 204 are two endpoints of the magnetic core 210 located outside the insulation cavity. In the implementation shown in FIG. 34, since the magnetic core 210 is located inside the insulation cavity in the plane formed by the first direction X and the third direction Z, the first endpoint 201 and the second endpoint 202 are two endpoints of the magnetic core 210 away from the flat plate portion 110, while the third endpoint 203 and the fourth endpoint 204 are two endpoints of the magnetic core 210 near the flat plate portion 110.

Along the first direction X, the first shielding layer 500 includes a first shielding end 501 and a second shielding end 502. The first shielding end 501 is located near the first endpoint 201, which can also be understood as the first shielding end 501 being located on one side of the first endpoint 201 away from the second endpoint 202. The second shielding end 502 is located near the second endpoint 202, which can also be understood as the second shielding end 502 being located on one side of the second endpoint 202 away from the first endpoint 201. That is to say, a length of the first shielding layer 500 in the first direction X is greater than that of the magnetic core 210 in the first direction X. Therefore, the first shielding layer 500 can be used to eliminate the electric-field-strength in the air around the magnetic core 210 in the first direction X, prolong the insulation life, and improve the reliability of the product.

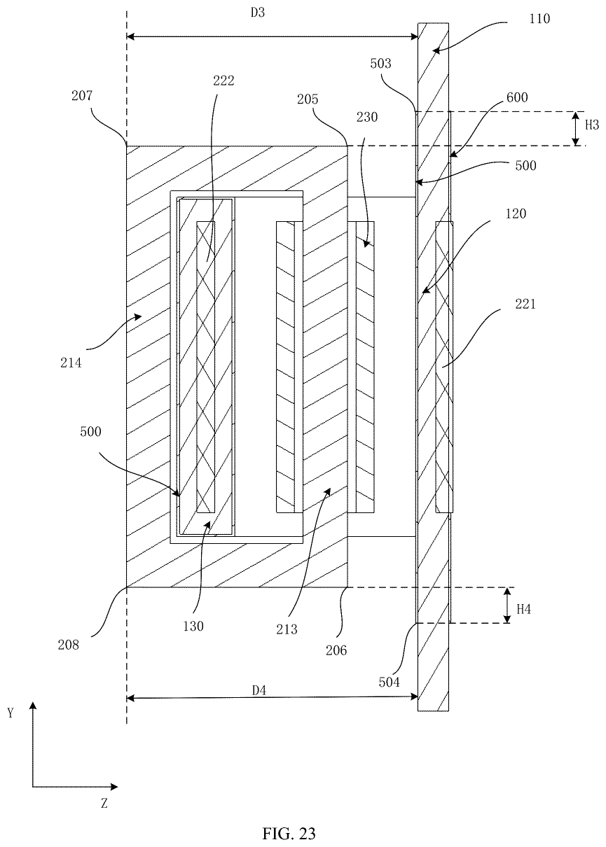

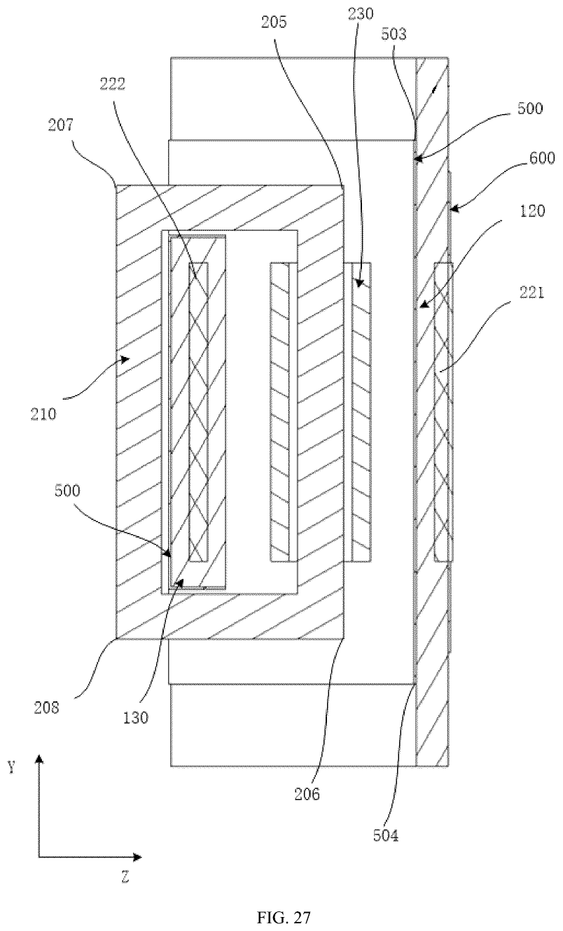

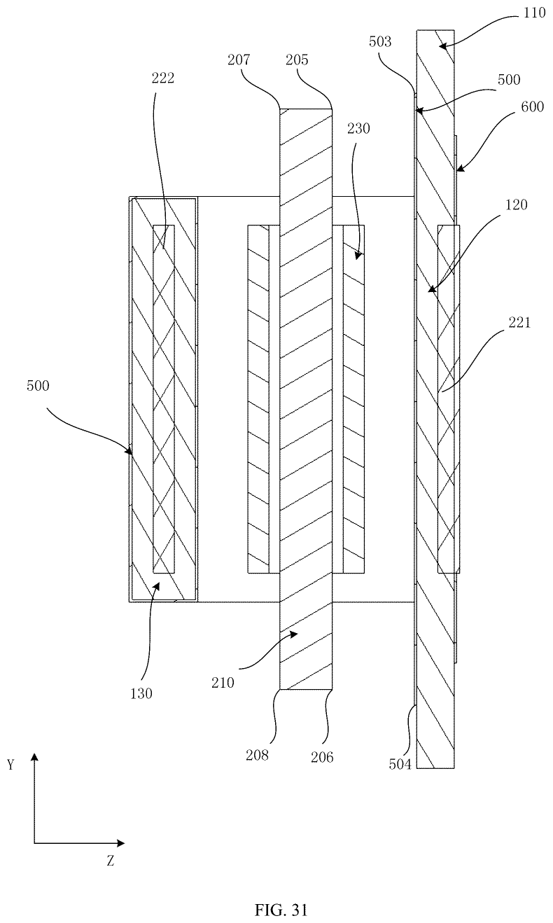

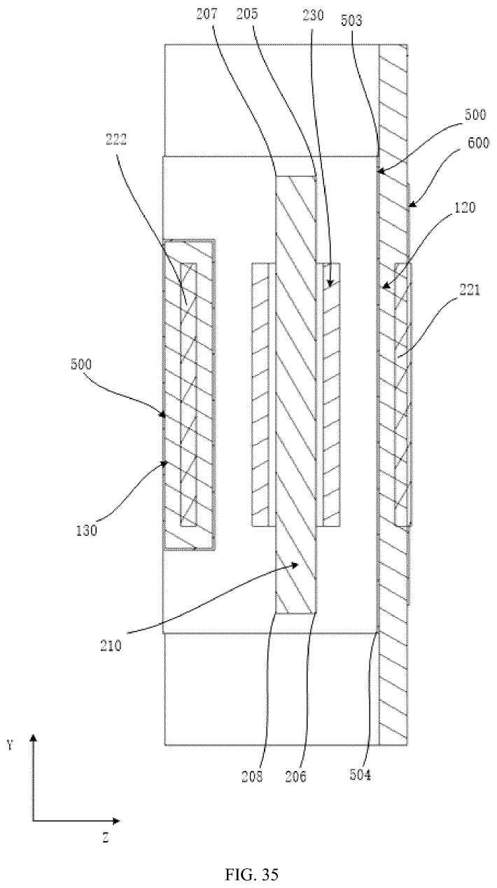

Please continue to refer to FIG. 23, FIG. 27, FIG. 31, and FIG. 35. When within a plane parallel to the third reference plane, which penetrates through the magnetic core 210 and the insulating board 100, in a cross-sectional view corresponding to the magnetic core 210 and the insulating board 100, the magnetic core 210 includes a fifth endpoint 205, a sixth endpoint 206, a seventh endpoint 207, and an eighth endpoint 208. That is, the fifth endpoint 205, the sixth endpoint 206, the seventh endpoint 207, and the eighth endpoint 208 are the four vertices of the magnetic core 210 in this plane, respectively. Along the third direction Z, the fifth endpoint 205 and the sixth endpoint 206 are located at two ends of the magnetic core 210 near the protrusion portion 120, respectively. The seventh endpoint 207 and the eighth endpoint 208 are located at two ends of the magnetic core 210 away from the protrusion portion 120, that is, the seventh endpoint 207 is located on one side of the fifth endpoint 205 away from the protrusion portion 120, and the eighth endpoint 208 is located on one side of the sixth endpoint 206 away from the protrusion portion 120.

Along the second direction Y, the first shielding layer 500 includes a third shielding end 503 and a fourth shielding end 504. The third shielding end 503 is located near the fifth endpoint 205, which can also be understood as the third shielding end 503 being located on one side of the fifth endpoint 205 away from the sixth endpoint 206. The fourth shielding end 504 is located near the sixth endpoint 206, which can also be understood as the fourth shielding end 504 being located on one side of the sixth endpoint 206 away from the fifth endpoint 205. That is to say, a length of the first shielding layer 500 in the second direction Y is greater than that of the magnetic core 210 in the second direction Y. Therefore, the first shielding layer 500 can be used to eliminate the electric-field-strength in the air around the magnetic core 210 in the second direction Y, prolong the insulation life, and improve the reliability of the product.

Please continue to refer to FIG. 23, FIG. 27, FIG. 31, and FIG. 35. In some possible implementations, along the second direction Y, a distance between the third shielding end 503 and the fifth endpoint 205 is H3, and along the third direction Z, a distance between the seventh endpoint 207 and the protrusion portion 120 is D3; wherein H3/D3 satisfies a condition of being greater than or equal to the third threshold and less than or equal to the fourth threshold. For example, in the present embodiment, the third threshold may be 1.5, and the fourth threshold may be 3, that is, 1.5≤H3/D3≤3. When H3/D3 is less than the third threshold, the shielding effect of the first shielding layer 500 is poor. When H3/D3 is greater than the fourth threshold, the shielding effect of the first shielding layer 500 does not significantly change. Therefore, when the first shielding layer 500 is set within the above parameter range, it can ensure that the first shielding layer 500 has a good shielding effect and will not have a significant impact on the power density of the power module.

Along the second direction Y, a distance between the fourth shielding end 504 and the six endpoint 206 is H4, and along the third direction Z, a distance between the eighth endpoint 208 and the protrusion portion 120 is D4, where H4/D4 satisfies a condition of being greater than or equal to the third threshold and less than or equal to the fourth threshold. The third threshold may be 1.5, and the fourth threshold may be 3, that is, 1.5≤H4/D4≤3. When H4/D4 is less than the third threshold, the shielding effect of the first shielding layer 500 is poor. When H4/D4 is greater than the fourth threshold, the shielding effect of the first shielding layer 500 does not significantly change. Therefore, when the first shielding layer 500 is set within the above parameter range, it can ensure that the first shielding layer 500 has a good shielding effect and will not have a significant impact on the power density of the power module.

The present embodiment sets the endpoint of the first shielding layer 500 in the second direction Y and the corresponding endpoint of the magnetic core in the second direction Y within the above ratio range, which can meet the shielding requirements and reduce the size of the first shielding layer 500 in the second direction Y.

In some implementations, due to that the transformer is connected with the circuit board and an electronic device, and sizes of the circuit board and the electronic device in the first direction X are relatively large, the first shielding layer 500 needs to be adjusted according to the sizes of these devices. In the first direction X, the size of the first shielding layer 500 needs to be larger than that of the circuit board and the electrical device.

Similarly, in other implementations, please continue to refer to FIG. 22, FIG. 26, FIG. 30, and FIG. 34. along the first direction X, a distance between the first shielding end 501 and the first endpoint 201 is H1, and along the third direction Z, a distance between the third endpoint 203 and the protrusion portion 120 is D1; H1/D1 satisfies a condition of being greater than or equal to the first threshold and less than or equal to the second threshold. The first threshold may be 1.5, and the second threshold may be 3, that is, 1.5≤H1/D1≤3. When H1/D1 is less than the first threshold, the shielding effect of the first shielding layer 500 is poor. When H1/D1 is greater than the second threshold, the shielding effect of the first shielding layer 500 does not significantly change. Therefore, when the first shielding layer 500 is set within the above parameter range, it can ensure that the first shielding layer 500 has a good shielding effect and will not have a significant impact on the power density of the power module.

Along the first direction X, a distance between the second shielding end 502 and the second endpoint 202 is H2, and along the third direction Z, a distance between the fourth endpoint 204 and the protrusion portion 120 is D2, where H2/D2 satisfies a condition of being greater than or equal to the first threshold and less than or equal to the second threshold. The first threshold may be 1.5, and the second threshold may be 3, that is, 1.5≤H2/D2≤3. When H4/D4 is less than the first threshold, the shielding effect of the first shielding layer 500 is poor. When H2/D2 is greater than the second threshold, the shielding effect of the first shielding layer 500 does not significantly change. Therefore, when the first shielding layer 500 is set within the above parameter range, it can ensure that the first shielding layer 500 has a good shielding effect and will not have a significant impact on the power density of the power module.

The present embodiment sets the endpoints of the first shielding layer 500 in the first direction X and the corresponding endpoints of the magnetic core in the first direction X within the above ratio range, which can meet the shielding requirements and reduce the size of the first shielding layer 500 in the first direction X. If the transformer is connected with the circuit board and an electronic device in the second direction Y, and sizes of the circuit board and the electronic device are relatively large, then the first shielding layer 500 needs to be adjusted according to the sizes of these devices. In the second direction Y, the size of the first shielding layer 500 needs to be larger than that of the circuit board and the electrical device.

In some possible implementations, the endpoints of the first shielding layer 500 in the first direction X and the corresponding endpoints of the magnetic core 210 in the first direction X, as well as the endpoints of the first shielding layer 500 in the second direction Y and the corresponding endpoints of the magnetic core in the second direction Y, may all need to meet the above ratio range. At this time, there are no external devices around the transformer, or there is no need to shield external devices, or the sizes of external electronic devices are small. The first shielding layer 500 can meet the shielding requirements and reduce the size of the first shielding layer 500 within the above ratio range.

Please continue to refer to FIG. 20, FIG. 24, FIG. 28, and FIG. 32. In the first reference plane, the projection of the first shielding layer 500 is located within the projection range of the insulating board 100, which means that the first shielding layer 500 does not exceed the range of the insulating board 100.

Furthermore, in the present embodiment, the first shielding layer 500 is provided on one side of the flat plate portion 110 along the third direction Z, a surface of the connecting bridge 130, and one side of the protrusion portion 120 facing towards the magnetic core 210.

Specifically, as shown in FIG. 20 to FIG. 23, the first shielding layer 500 is provided on one side of the flat plate portion 110 facing towards the magnetic core 210 along the third direction Z, one side of the protrusion portion 120 facing towards the magnetic core 210, and the surface of the connecting bridge 130. There is a through-hole inside the connecting bridge 130 (i.e., the through-hole penetrates through the interior of the connecting bridge 130), the second part 222 of the first winding 220 is provided inside the through-hole of the connecting bridge 130, and the first shielding layer 500 is provided on an inner surface of the through-hole and an outer surface of the connecting bridge 130. The first shielding layer 500 provided on the connecting bridge 130 plays an electromagnetic shielding role for the second part 222 of the first winding 220.

As shown in FIG. 24 to FIG. 27, the first shielding layer 500 is provided on one side of the flat plate portion 110 away from the magnetic core 210 along the third direction Z, one side of the protrusion portion 120 facing towards the magnetic core 210, and the surface of the connecting bridge 130. The connecting bridge 130 includes the through-hole. The second part 222 of the first winding 220 is provided inside the through-hole of the connecting bridge 130, and the first shielding layer 500 is provided on the inner surface of the through-hole and the inner and outer surfaces of the connecting bridge 130. The first shielding layer 500 provided on the connecting bridge 130 plays an electromagnetic shielding role for the second part 222 of the first winding 220. If the external electronic device is small or does not need to be shielded along the first direction X, then the first shielding layer 500 may not be provided on one side of the flat plate portion 110 facing away from the protrusion portion 120 along the third direction Z.

As shown in FIG. 28 to FIG. 31, the first shielding layer 500 is provided on one side of the flat plate portion 110 facing towards the magnetic core 210 along the third direction Z, one side of the protrusion portion 120 facing towards the magnetic core 210, the surface of the connecting bridge 130, and a surface of the partition board 150. The connecting bridge 130 and the partition board 150 include the through-hole. The second part 222 of the first winding 220 is provided inside the through-hole, and the first shielding layer 500 is provided on the inner surface of the through-hole, the outer surface of the connecting bridge 130 and the surface of the partition board 150. The first shielding layer 500 provided on the connecting bridge 130 and the partition board 150 plays an electromagnetic shielding role for the second part 222 of the first winding 220.

As shown in FIG. 32 to FIG. 35, the first shielding layer 500 is provided on one side of the flat plate portion 110 away from the magnetic core 210 along the third direction Z, one side of the protrusion portion 120 facing towards the magnetic core 210, the surface of the connecting bridge 130, and the surface of the partition board 150. The connecting bridge 130 and the partition board 150 include the through-hole. The second part 222 of the first winding 220 is provided inside the through-hole, and the first shielding layer 500 is provided on the inner surface of the through-hole, the inner and outer surface of the connecting bridge 130 and the surface of the partition board 150. The first shielding layer 500 provided on the connecting bridge 130 and the partition board 150 plays an electromagnetic shielding role for the second part 222 of the first winding 220. If the external electronic device is small or does not need to be shielded along the first direction X, then the first shielding layer 500 may not be provided on one side of the flat plate portion 110 facing away from the protrusion portion 120 along the third direction Z. In some possible implementations, a side of the insulating board 100 facing towards the magnetic core 210 is further provided with a second shielding layer (not shown in the figure). The second shielding layer is connected with the first shielding layer 500 and surrounds an outer periphery of the first shielding layer 500, resistivity of the second shielding layer is greater than that of the first shielding layer 500.

For example, the second shielding layer is also a semiconducting layer, and the material of the second shielding layer includes a graphene or a carbon black. The first shielding layer 500 and the second shielding layer can be integrally formed. The conductivity of the first shielding layer 500 and the second shielding layer (resistivity and conductivity are reciprocal to each other) can be uniform or non-uniform. Moreover, minimum conductivity of the first shielding layer 500 is greater than maximum conductivity of the second shielding layer.

In an implementation, the first shielding layer 500 and the second shielding layer can be made of different materials, and the conductivity of the material used in the first shielding layer 500 is greater than that of the material used in the second shielding layer. Alternatively, the first shielding layer 500 and the second shielding layer can be made of the same material, but the concentration of conductive material in the first shielding layer 500 is greater than that in the second shielding layer. Alternatively, the material thickness of the first shielding layer 500 may be greater than that of the second shielding layer.

The present embodiment can reduce the electric field strength at the edge of the first shielding layer 500, reduce the occurrence of discharge, and increase the product life by setting a second shielding layer on the outer peripheral side of the first shielding layer 500.

Please continue to refer to FIG. 20 to FIG. 35, one side of the insulating board 100 facing towards the first part 221 is further provided with a third shielding layer 600. For example, the third shielding layer 600 is a semiconducting layer, and the material of the third shielding layer includes a graphene or a carbon black. In the first reference plane, the projection of the first part 221 is located in the projection range of the third shielding layer 600.

Through the above structures, the present embodiment can adjust the electric-field-strength in the air around the first part 221 through the third shielding layer 600, prolong the insulation life, and improve the reliability of the product.

Furthermore, one side of the insulating board 100 facing towards the first part 221 is further provided with a fourth shielding layer (not shown). The fourth shielding layer is connected with the third shielding layer 600 and surrounds an outer periphery of the third shielding layer 600, resistivity of the fourth shielding layer is greater than that of the third shielding layer 600.

For example, the fourth shielding layer is also a semiconducting layer, and the material of the fourth shielding layer includes a graphene or a carbon black. The third shielding layer 600 and the fourth shielding layer can be integrally formed. The conductivity of the third shielding layer 600 and the fourth shielding layer can be uniform or non-uniform. Moreover, minimum conductivity of the third shielding layer 600 is greater than maximum conductivity of the fourth shielding layer.

In an implementation, the third shielding layer 600 and the fourth shielding layer can be made of different materials, and the conductivity of the material used in the third shielding layer 600 is greater than that of the material used in the fourth shielding layer. Alternatively, the third shielding layer 600 and the fourth shielding layer can be made of the same material, but the concentration of conductive material in the third shielding layer 600 is greater than that in the fourth shielding layer. Alternatively, the material thickness of the third shielding layer 600 may be greater than that of the fourth shielding layer.

The present embodiment can reduce the electric field strength at the edge of the third shielding layer 600, reduce the occurrence of discharge, and increase the product life by setting the fourth shielding layer on the outer peripheral side of the third shielding layer 600.

In an implementation, the resistivity of the selected materials for the first shielding layer 500 and the third shielding layer 600 can be the same, or the resistivity of the selected materials can be different according to actual requirements.

In an implementation, the resistivity of the selected materials for the second and fourth shielding layers can be the same, or the resistivity of the selected materials can be different according to actual requirements.

In an implementation, the magnetic core 210 can be a U-shaped magnetic core, an E-shaped magnetic core, or other shaped magnetic cores. In the second reference plane, the magnetic core 210 includes vertices near the protrusion portion 120 and vertices away from the protrusion portion 120. In the third reference plane, the magnetic core 210 includes vertices near the protrusion portion 120 and vertices away from the protrusion portion 120.

In the description of the present application, it should be understood that the orientation or positional relationship indicated by the terms “center”, “longitudinal”, “transverse”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential” and other terms is based on the orientation or positional relationship shown in the accompanying drawings, and is only for the convenience of describing the present application and simplifying the description, rather than indicating or implying that the apparatus or component referred to must have a specific orientation, or be constructed and operated in a specific orientation, therefore they cannot be understood as a limitation on the present application.

In the present application, unless otherwise specified and limited, the terms “installation”, “connection”, “link”, “fixation” and other terms should be broadly understood, for example, they may be fixed connections, detachable connections, or integrated; they may be directly connected or indirectly connected through an intermediate medium, they may be the internal connection of two components or the interaction relationship between two components. For those of ordinary skill in the art, the specific meanings of the above terms in the present application may be understood based on specific situations.

It should be noted that in the description of the present application, the terms “first” and “second” are only used for the convenience of describing different components, and cannot be understood as indicating or implying sequential relationships, relative importance, or implicitly indicating the quantity of technical features. Therefore, the features limited by “first” and “second” may explicitly or implicitly include at least one of these features.

In the present application, each embodiment or implementation is described in a progressive manner, and each embodiment focuses on the differences from other embodiments, the same and similar parts between each embodiment may be referred to each other.

In the description of the present application, the reference terms “one embodiment”, “some embodiments”, “illustrative embodiments”, “examples”, “specific examples”, or “some examples” and other descriptions refer to specific features, structures, materials, or characteristics described in combination with embodiments or examples included in at least one embodiment or example of the present application. In the present application, the illustrative expressions of the above terms may not necessarily refer to the same implementation or example. Moreover, the described specific features, structures, materials, or characteristics may be appropriately combined in any one or more embodiments or examples.

Finally, it should be noted that: the above embodiments are only used to illustrate the technical solutions of the present application, rather than limitation; although the present application has been illustrated in detail with reference to the foregoing embodiments, those of ordinary skill in the art should understand that: the technical solutions recorded in the foregoing embodiments may still be modified, or some or all of the technical features may be equivalently substituted; and these modifications or substitutions do not make the essence of the corresponding technical solutions deviate from the scope of the technical solutions of the embodiments of the present application.

What is claimed is:

1. A power module, comprising:
an insulating board, comprising a flat plate portion;
a transformer, comprising a magnetic core and a first winding wound on the magnetic core, wherein the first winding comprises a first part and a second part connected electrically, wherein the first part is located on one side of the insulating board away from the magnetic core, and the second part is set within the insulating board;
a first shielding layer which is set at least on one side of the insulating board facing towards the magnetic core;
wherein in a first reference plane parallel to the flat plate portion, a projection of the magnetic core is located in a projection range of the first shielding layer.

2. The power module according to claim 1, wherein the insulating board further comprises a protrusion portion and a connecting bridge; the flat plate portion is parallel to the first reference plane formed by a first direction and a second direction; the protrusion portion and/or the connecting bridge protrude from the flat plate portion along a third direction to form an insulation cavity; at least part of the magnetic core is set within the insulation cavity; the first part is located on one side of the protrusion portion away from the insulation cavity, and the second part is located within the connecting bridge, the transformer further comprises a second winding, the second winding is directly wound on the magnetic core;
the magnetic core comprises a first vertical pillar and a second vertical pillar arranged opposite to each other, as well as a first transverse pillar and a second transverse pillar arranged opposite to each other; the first vertical pillar, the first transverse pillar, the second vertical pillar, and the second transverse pillar are connected head-to-tail in sequence;
wherein every two of the first direction, the second direction, and the third direction are perpendicular to each other.

3. The power module according to claim 2, wherein within a plane parallel to a second reference plane formed by the first direction and the third direction, the magnetic core comprises a first endpoint, a second endpoint, a third endpoint, and a fourth endpoint; along the third direction, the first endpoint and the second endpoint are located at two ends of the magnetic core near the protrusion portion, respectively, and the third endpoint and the fourth endpoint are located at two ends of the magnetic core away from the protrusion portion, respectively; along the first direction, the first shielding layer comprises a first shielding end and a second shielding end, wherein the first shielding end is close to the first endpoint and the second shielding end is close to the second endpoint.

4. The power module according to claim 2, wherein within a plane parallel to a third reference plane formed by the second direction and the third direction, the magnetic core comprises a fifth endpoint, a sixth endpoint, a seventh endpoint, and an eighth endpoint; along the third direction, the fifth endpoint and the sixth endpoint are located at two ends of the magnetic core near the protrusion portion, respectively, and the seventh endpoint and the eighth endpoint are located at two ends of the magnetic core away from the protrusion portion, respectively; along the second direction, the first shielding layer comprises a third shielding end and a fourth shielding end, wherein the third shielding end is close to the fifth endpoint and the fourth shielding end is close to the sixth endpoint.

5. The power module according to claim 3, wherein along the first direction, a distance between the first shielding end and the first endpoint is H1, and along the third direction, a distance between the third endpoint and the protrusion portion is D1; along the first direction, a distance between the second shielding end and the second endpoint is H2, and along the third direction, a distance between the fourth endpoint and the protrusion portion is D2, wherein H1/D1 and H2/D2 satisfies a condition of being greater than or equal to a first threshold and less than or equal to a second threshold.

6. The power module according to claim 5, wherein the first threshold is 1.5, and the second threshold is 3.

7. The power module according to claim 4, wherein along the second direction, a distance between the third shielding end and the fifth endpoint is H3, and along the third direction, a distance between the seventh endpoint and the protrusion portion is D3; along the second direction, a distance between the fourth shielding end and the six endpoint is H4, and along the third direction, a distance between the eighth endpoint and the protrusion portion is D4, wherein H3/D3 and H4/D4 satisfies a condition of being greater than or equal to a third threshold and less than or equal to a fourth threshold.

8. The power module according to claim 7, wherein the third threshold is 1.5, and the fourth threshold is 3.

9. The power module according to claim 2, wherein in the first reference plane, a projection of the first shielding layer is located in a projection range of the insulating board.

10. The power module according to claim 2, wherein the first shielding layer is provided on one side of the flat plate portion along the third direction, a surface of the connecting bridge, and one side of the protrusion portion facing towards the magnetic core.

11. The power module according to claim 1, further comprising a second shielding layer, which is provided on one side of the insulating board facing towards the magnetic core, wherein the second shielding layer is connected with the first shielding layer and surrounds an outer periphery of the first shielding layer, and resistivity of the second shielding layer is greater than that of the first shielding layer.

12. The power module according to claim 1, further comprising a third shielding layer, which is provided on one side of the insulating board facing towards the first part, wherein in the first reference plane, a projection of the first part is located in a projection range of the third shielding layer.

13. The power module according to claim 12, further comprising a fourth shielding layer, which is provided on one side of the insulating board facing towards the first part, wherein the fourth shielding layer is connected with the third shielding layer and surrounds an outer periphery of the third shielding layer, and resistivity of the fourth shielding layer is greater than that of the third shielding layer.

14. The power module according to claim 2, wherein along the third direction, a distance between the connecting bridge and the flat plate portion is zero, the protrusion portion protrudes from the flat plate portion, the first transverse pillar is located within the insulation cavity, the second transverse pillar is located outside the insulation cavity, the second winding is wound on the first transverse pillar.

15. The power module according to claim 2, wherein along the third direction, a distance between the protrusion portion and the flat plate portion is zero, the connecting bridge protrudes from the flat plate portion, the first transverse pillar is located within the insulation cavity, the second transverse pillar is located outside the insulation cavity, the second winding is wound on the first transverse pillar.

16. The power module according to claim 2, wherein the insulating board further comprises a partition board, which is located within the insulation cavity, the protrusion portion is connected with the connecting bridge by the partition board, and the partition board divides the insulation cavity into a first insulation cavity and a second insulation cavity, the first transverse pillar is located within the first insulation cavity, and the second transverse pillar is located within the second insulation cavity.

17. The power module according to claim 16, wherein the transformer comprises two first windings and two second windings, the two first windings are respectively wound on outer sides of the two second windings, the first parts of the two first windings are respectively set on one side of the protrusion portion away from the insulation cavity, the second parts of the two first windings are respectively set within the partition board and the connecting bridge, the two second windings are respectively wound on the first transverse pillar and the second transverse pillar.

18. The power module according to claim 16, wherein along the third direction, a distance between the protrusion portion and the flat plate portion is zero, the connecting bridge protrudes from the flat plate portion.

19. The power module according to claim 16, wherein along the third direction, a distance between the connecting bridge and the flat plate portion is zero, the protrusion portion protrudes from the flat plate portion.
